(19) United States
(12) Patent Application Publication
(10) Pub. No.: US 2017/0250153 A1
(43) Pub. Date: Aug. 31, 2017

(54) ELECTRONIC PART, ELECTRONIC DEVICE, AND ELECTRONIC APPARATUS

(71) Applicant: FUJITSU LIMITED, Kawasaki-shi (JP)

(72) Inventors: Ryo Kikuchi, Sagamihara (JP); TOSHIYA AKAMATSU, Zama (JP)

(73) Assignee: FUJITSU LIMITED, Kawasaki-shi (JP)

(21) Appl. No.: 15/397,314

(22) Filed: Jan. 3, 2017

(30) Foreign Application Priority Data
Feb. 26, 2016 (JP) 2016-036149

(51) Int. Cl. H01L 23/00

(52) U.S. Cl. CPC H01L 24/14; H01L 24/17; H01L 24/11; H01L 24/81; H01L 2224/1403; H01L 2224/13017; H01L 2224/13022; H01L 2224/13082; H01L 2224/13083; H01L 2224/13007; H01L 2224/13014; H01L 2224/81193; H01L 2224/16112; H01L 2224/16238; H01L 2224/16148; H01L 2224/16227; H01L 2224/16145; H01L 2224/81191; H01L 2924/13091; H01L 2224/32225; H01L 2224/48091; H01L 2224/48106; H01L 2224/48228; H01L 2224/73265; H01L 2224/73204; H01L 23/3121

(57) ABSTRACT

An electronic part includes a substrate, an insulating film formed over the substrate, a first pillar electrode, a first solder formed over the first pillar electrode, a second pillar electrode, and a second solder formed over the second pillar electrode. The first pillar electrode over which the first solder is formed is formed over a first region of an insulating film including a level difference between a first opening portion and a peripheral portion of the first opening portion. The second pillar electrode over which the second solder is formed is formed over a second region of the insulating film including a second opening portion whose opening area is larger than that of the first opening portion. For example, the second pillar electrode over which the second solder is formed is formed over the second opening portion of the insulating film.

### CROSS-REFERENCE TO RELATED APPLICATION

This application is based upon and claims the benefit of priority of the prior Japanese Patent Application No. 2016-036149, filed on Feb. 26, 2016, the entire contents of which are incorporated herein by reference.

### FIELD

The embodiments discussed herein are related to an electronic part, an electronic device, and an electronic apparatus.

### BACKGROUND

The technique of forming a group of pillar electrodes over an electronic part, such as a semiconductor chip, or the technique of forming a group of pillar electrodes which differ in diameter is known. Furthermore, the technique of electrically connecting an electronic part in which solders formed over upper surfaces of a group of pillar electrodes are reflowed (wet back process) in advance at a determined temperature to another electronic part by the use of the solders is known.

See, for example, Japanese Laid-open Patent Publication Nos. 2013-110151 and 2014-132635.

There may be differences in the position of an upper end after a wet back process among solders formed over the upper surfaces of a group of pillar electrodes due to, for example, the differences in diameter or arrangement among the group of pillar electrodes. If there are such differences in the position of an upper end after a wet back process among solders in an electronic part, solders over part (one or more pillar electrodes) of a group of pillar electrodes are not electrically connected to another electronic part. As a result, there are nonconnected portions. Alternatively, even if the two electronic parts are connected, there is a deficiency of the strength of connecting portions. Accordingly, connection reliability may deteriorate.

In addition, deterioration in connection reliability caused by such nonconnection or a deficiency of strength may also occur when an electronic part in which the positions of the upper ends of a group of solders are uniform is connected to another electronic part in which there are differences in the position of an upper end among a group of terminals.

### SUMMARY

According to an aspect, there is provided an electronic part including a substrate, an insulating film formed over the substrate, having a first region including a first opening portion and a first peripheral portion of the first opening portion, and having a second region including a second opening portion whose opening area is larger than an opening area of the first opening portion, a first pillar electrode formed over the first region, a first solder formed over the first pillar electrode, a second pillar electrode formed over the second region, and a second solder formed over the second pillar electrode.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are views for describing an example of an electronic part including a group of pillar electrodes which differ in diameter;

FIGS. 2A and 2B are views for describing another example of an electronic part including a group of pillar electrodes which differ in diameter;

FIGS. 3A and 3B illustrate an example of an electronic part according to a first embodiment;

FIG. 4 is a view for describing terminals of the electronic part according to the first embodiment (part 1);

FIG. 5 is a view for describing terminals of the electronic part according to the first embodiment (part 2);

FIGS. 6A and 6B illustrate a first modification of the electronic part according to the first embodiment;

FIGS. 7A and 7B illustrate a second modification of the electronic part according to the first embodiment;

FIGS. 8A and 8B illustrate other examples of an opening portion of an insulating film according to the first embodiment (part 1);

FIGS. 9A and 9B illustrate other examples of the opening portion of the insulating film according to the first embodiment (part 2);

FIGS. 10A and 10B illustrate other examples of the opening portion of the insulating film according to the first embodiment (part 3);

FIGS. 11A through 11C illustrate an example of a method for fabricating the electronic part according to the first embodiment (part 1);

FIGS. 12A through 12C illustrate an example of a method for fabricating the electronic part according to the first embodiment (part 2);

FIGS. 13A through 13C illustrate an example of a method for fabricating the electronic part according to the first embodiment (part 3);

FIGS. 14A and 14B are examples of an image of a section of an electronic part;

FIGS. 15A and 15B illustrate a first example of connection between the electronic part according to the first embodiment and another electronic part;

FIGS. 16A and 16B illustrate a second example of connection between the electronic part according to the first embodiment and another electronic part;

FIGS. 17A and 17B are views for describing variation in the height of a group of pillar electrodes;

FIGS. 18A and 18B illustrate examples of an electronic part according to a second embodiment;

FIGS. 19A and 19B illustrate an example of connection between the electronic part according to the second embodiment and another electronic part;

FIG. 20 illustrates an example of the structure of a semiconductor chip;

FIGS. 21A and 21B illustrate an example of the structure of a semiconductor package;

FIG. 22 illustrates another example of the structure of a semiconductor package;

FIG. 23 illustrates an example of the structure of a circuit board; and

FIG. 24 illustrates an example of an electronic equipment.

### DESCRIPTION OF EMBODIMENTS

First an electronic part including a group of pillar electrodes will be described.

An electronic part including a group of pillar electrodes which differ in diameter will be taken as an example.

A relatively minute terminal is realized by a pillar electrode. With electronic parts such as large-scale integration (LSI) chips, the density of terminals is improved or the number of terminals is increased. As a result, for example, the functions of such electronic parts are enhanced. For example, by using pillar electrodes as terminals of electronic parts used for 2.5-dimensional mounting or 3-dimensional mounting, the length of wirings between the electronic parts is reduced. As a result, for example, transmission performance is improved.

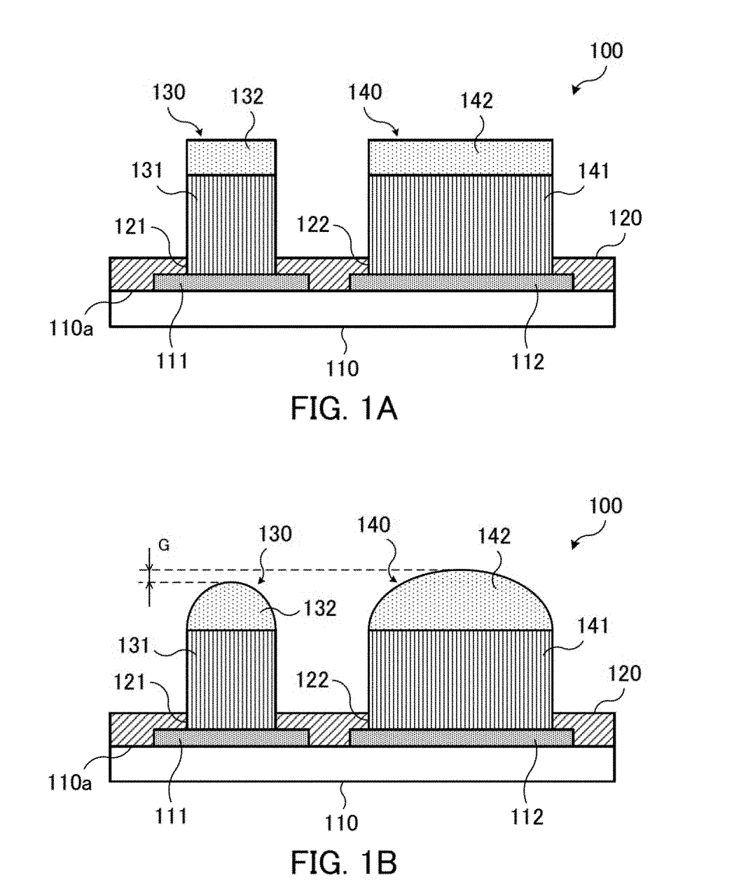

With electronic parts in which pillar electrodes are used as terminals, signal transmission terminals become minuter. However, on the other hand, in order to ensure current density resistance, pillar electrodes whose diameters are larger than those of pillar electrodes used as signal transmission terminals may be preferable for power supply terminals. If a group of pillar electrodes which differ in diameter are formed in an electronic part, a state illustrated in FIG. 1A, 1B, 2A, or 2B may arise.

FIGS. 1A and 1B are views for describing an example of an electronic part including a group of pillar electrodes which differ in diameter. FIG. 1A is a fragmentary schematic sectional view of an electronic part before a wet back process. FIG. 1B is a fragmentary schematic sectional view of the electronic part after a wet back process.

An electronic part 100 illustrated in FIG. 1A includes a semiconductor chip, a semiconductor device such as a semiconductor package, a group of semiconductor devices, a circuit board such as a printed circuit board or an interposer, or a group of circuit boards.

The electronic part 100 includes a substrate 110, an insulating film 120, a terminal 130, and a terminal 140. The electronic part 100 including the two terminals 130 and 140 is taken as an example. However, the number of terminals included in the electronic part 100 is not limited to two.

The substrate 110 is a body of the electronic part 100. A pad electrode 111 and a pad electrode 112 electrically connected to circuit elements inside the substrate 110 are formed over a surface 110a of the substrate 110. The pad electrode 111 and the pad electrode 112 are formed by the use of a conductor material such as aluminum (Al) or copper (Cu).

The insulating film 120 is formed over the surface 110a of the substrate 110 and functions as a passivation film (protection film). An opening portion 121 and an opening portion 122 leading to the pad electrode 111 and the pad electrode 112, respectively, over the substrate 110 are formed in the insulating film 120.

The terminal 130 has a pillar electrode 131 formed over the pad electrode 111 which is exposed from the opening portion 121 of the insulating film 120 and a solder 132 formed over the pillar electrode 131. The terminal 140 has a pillar electrode 141 formed over the pad electrode 112 which is exposed from the opening portion 122 of the insulating film 120 and a solder 142 formed over the pillar electrode 141.

The diameter of the pillar electrode 131 of the terminal 130 is smaller than the diameter of the pillar electrode 141 of the terminal 140. The opening portion 121 in which the pillar electrode 131 of relatively small diameter is formed and the pad electrode 111 over which the pillar electrode 131 of relatively small diameter is formed are smaller in plane size than the opening portion 122 in which the pillar electrode 141 of relatively large diameter is formed and the pad electrode 112 over which the pillar electrode 141 of relatively large diameter is formed.

The pillar electrode 131 of the terminal 130 and the pillar electrode 141 of the terminal 140 are formed by the use of various conductor materials. For example, the pillar electrode 131 and the pillar electrode 141 are formed by the use of Cu. Various solder materials are used for forming the solder 132 over the pillar electrode 131 and forming the solder 142 over the pillar electrode 141. For example, a Sn—Ag based solder containing tin (Sn) and silver (Ag) is used for forming the solder 132 and the solder 142.

The pillar electrode 131 and the pillar electrode 141 are formed by the use of, for example, a plating method. The solder 132 and the solder 142 are also formed by the use of, for example, the plating method. FIG. 1A illustrates the terminal 130 having the pillar electrode 131 and the solder 132 formed in this way by the use of the plating method and the terminal 140 having the pillar electrode 141 and the solder 142 formed in this way by the use of the plating method.

A wet back process by reflow is performed on the terminal 130 and the terminal 140. FIG. 1B illustrates the terminal 130 and the terminal 140 after the wet back process. By performing the wet back process, the solder 132 of the terminal 130 and the solder 142 of the terminal 140 are melted once and then frozen (solidified). Each of the solder 132 and the solder 142 has a roundish shape as a result of the action of surface tension at melting time. The wet back process is performed in order to, for example, inspect the height of the terminal 130 and the terminal 140 with accuracy.

As illustrated in FIG. 1A, with the electronic part 100 in which the terminal 130 and the terminal 140 having different diameters are formed, the amount of the solder 132 formed over the pillar electrode 131 of relatively small diameter is smaller than the amount of the solder 142 formed over the pillar electrode 141 of relatively large diameter. Accordingly, as illustrated in FIG. 1B, the solder 132 over the pillar electrode 131 of relatively small diameter is thinner than the solder 142 over the pillar electrode 141 of relatively large diameter after the wet back process. That is to say, there is a height difference G between the terminal 130 and the terminal 140.

If the height gap G occurs between the terminal 130 and the terminal 140 after the wet back process, the following problem arises. When the electronic part 100 is connected to a second electronic part, the terminal 130 may fail to be electrically connected to a corresponding terminal of the second electronic part. As a result, there may be a nonconnected portion. Alternatively, even if the electronic part 100 is electrically connected to the second electronic part, there may be a deficiency of the strength of a connecting portion.

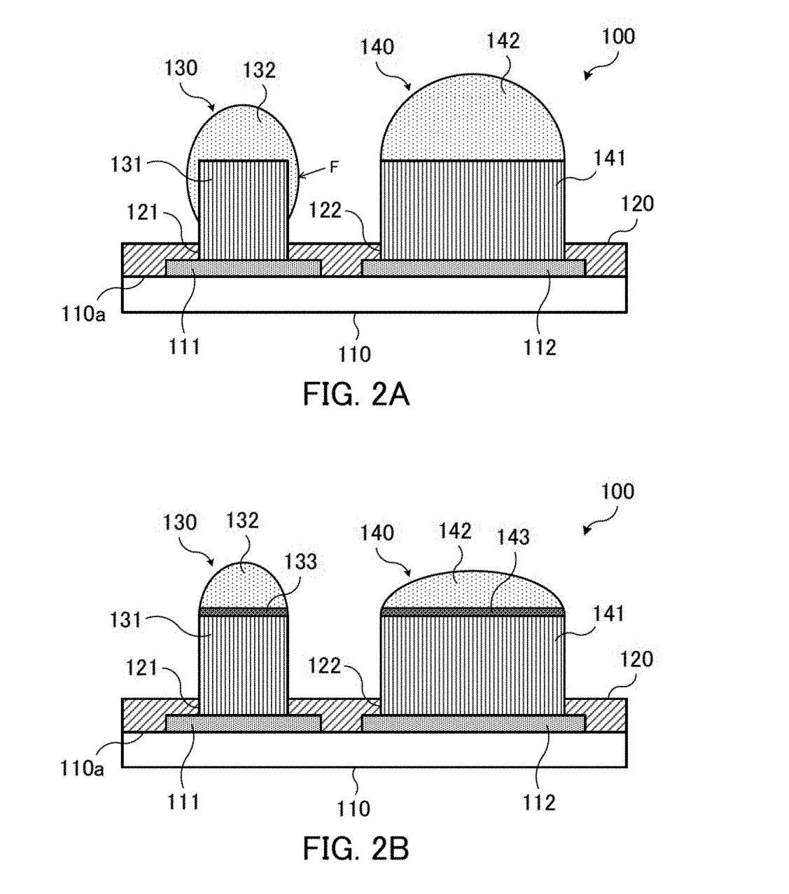

FIGS. 2A and 2B are views for describing another example of an electronic part including a group of pillar electrodes which differ in diameter. Each of FIGS. 2A and 2B is a fragmentary schematic sectional view of an electronic part after a wet back process.

When a solder 132 and a solder 142 are formed in an electronic part 100 in which a terminal 130 and a terminal 140 having different diameters are formed, the amount of the solder 132 and the amount of the solder 142 may be controlled with a pillar electrode 141 of relatively large diameter, for example, as reference. In that case, a state illustrated in FIG. 2A may arise.

That is to say, if the solder 132 and the solder 142 are formed on the basis of an amount determined with the pillar electrode 141 of relatively large diameter as reference, the amount of the solder 132 formed over a pillar electrode 131 of relatively small diameter may be excessive. In this case, as illustrated in FIG. 2A, the solder 132 melted by the wet back process may flow from the upper surface to the side of the pillar electrode 131. That is to say, what is called a solder spill F may occur. If the solder spill F occurs, there occurs a height gap between the terminal 130 and the terminal 140. As a result, when the electronic part 100 is connected to another electronic part, there may be a nonconnected portion. Alternatively, even if the electronic part 100 is electrically connected to another electronic part, there may be a deficiency of the strength of a connecting portion. This is the same with FIG. 1B. In addition, with the electronic part 100 in which the solder spill F has occurred, the solder 132 of the terminal 130 which has spilled may spread in a wider range. In that case, the solder 132 may come in contact with other terminals (such as the terminal 140) adjacent to the terminal 130 and a short circuit may occur.

On the other hand, if the amount of the solder 132 and the amount of the solder 142 are controlled with the pillar electrode 131 of relatively small diameter, for example, as reference at the time of forming the solder 132 and the solder 142, the amount of the solder 142 formed over the pillar electrode 141 of relatively large diameter may be insufficient. That is to say, if the solder 132 and the solder 142 are formed on the basis of an amount determined with the pillar electrode 131 of relatively small diameter as reference, the above solder spill F is prevented on the terminal 130 side. On the terminal 140 side, however, it may be difficult to ensure the amount of the solder 142 needed for connecting the electronic part 100 to another electronic part.

As illustrated in FIG. 2B, for example, an intermetallic compound 133 and an intermetallic compound 143 may be formed between the pillar electrode 131 and the solder 132 and between the pillar electrode 141 and the solder 142, respectively, at the time of the wet back process. Part of the solder 142 is consumed for forming the intermetallic compound 143. Accordingly, the amount of the solder 142 used for connecting the electronic part 100 to another electronic part is reduced from the amount of the solder 142 determined with the pillar electrode 131 of relatively small diameter as reference. As a result, when the electronic part 100 is connected to another electronic part, there may be a nonconnected portion. Alternatively, even if the electronic part 100 is electrically connected to another electronic part, there may be a deficiency of the strength of a connecting portion. Furthermore, because the amount of the solder 142 is smaller than a proper amount, a height gap may occur between the terminal 130 and the terminal 140. As a result, when the electronic part 100 is connected to another electronic part, there may be a nonconnected portion. Alternatively, even if the electronic part 100 is electrically connected to another electronic part, there may be a deficiency of the strength of a connecting portion.

The height gap G (FIG. 1B), the solder spill F (FIG. 2A), or a deficiency in the height or amount of the solder 132 or the solder 142 (FIG. 2A or 2B) in the electronic part 100 causes a failure of connection between the electronic part 100 and another electronic part. As a result, the reliability of connection between the electronic part 100 and another electronic part may deteriorate.

In view of the above problems, a technique indicated in a first embodiment described below will be adopted to realize an electronic part connected to another electronic part with high reliability and an electronic device including a group of electronic parts connected with high reliability.

A first embodiment will now be described.

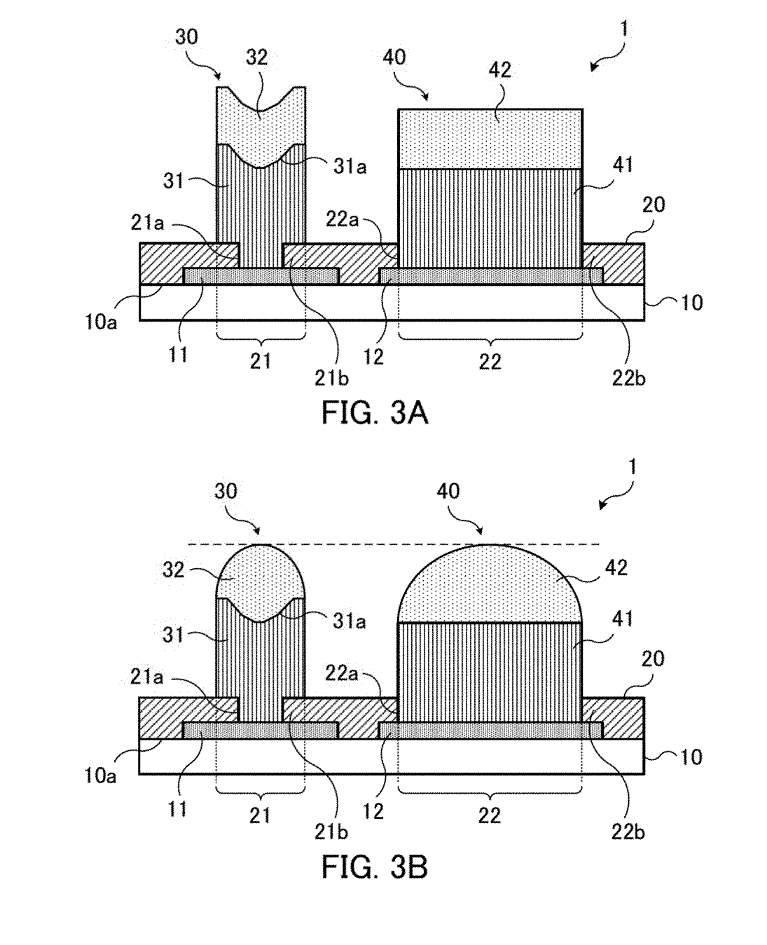

FIGS. 3A and 3B illustrate an example of an electronic part according to a first embodiment. FIG. 3A is a fragmentary schematic sectional view of an electronic part before a wet back process. FIG. 3B is a fragmentary schematic sectional view of the electronic part after a wet back process.

For example, an electronic part 1 illustrated in FIG. 3A includes a semiconductor chip, a semiconductor device such as a semiconductor package, a group of semiconductor devices, a circuit board such as a printed circuit board or an interposer, or a group of circuit boards. The electronic part 1 may be a semiconductor device obtained by dicing a group of semiconductor devices included in a substrate, the substrate before dicing the group of semiconductor devices, a circuit board obtained by dicing a group of circuit boards included in a substrate, or the substrate before dicing the group of circuit boards.

The electronic part 1 includes a substrate 10, an insulating film 20, a terminal 30, and a terminal 40. The electronic part 1 including the two terminals 30 and is taken as an example. However, the number of terminals included in the electronic part 1 is not limited to two.

The substrate 10 is a body of the electronic part 1. A pad electrode 11 and a pad electrode 12 electrically connected to circuit elements inside the substrate 10 are formed over a surface 10a of the substrate 10. The pad electrode 11 and the pad electrode 12 are formed by the use of a conductor material such as Al or Cu.

The insulating film 20 is formed over the surface 10a of the substrate 10 and functions as a passivation film. The insulating film 20 is formed by the use of an organic insulating material, such as polyimide, or inorganic insulating material, such as silicon oxide (SiO) or silicon nitride (SiN). An opening portion 21a and an opening portion 22a leading to the pad electrode 11 and the pad electrode 12, respectively, over the substrate 10 are formed in the insulating film 20. The opening area of the opening portion 21a is smaller than the opening area of the opening portion 22a.

The terminal 30 has a pillar electrode 31 and a solder 32 formed over the pillar electrode 31. The pillar electrode 31 of the terminal 30 is smaller in diameter than a pillar electrode 41 of the terminal 40. The pillar electrode 31 is formed over a region 21 of the insulating film 20 including the opening portion 21a and a peripheral portion 21b of the opening portion 21a. The pillar electrode 31 is formed in this way over the region 21 including a level difference between the opening portion 21a and the peripheral portion 21b. As illustrated in FIG. 3A, for example, a portion corresponding to the opening portion 21a sinks and a concavity 31a is formed in the upper surface of the pillar electrode 31.

The terminal 40 has the pillar electrode 41 and a solder 42 formed over the pillar electrode 41. The diameter of the pillar electrode 41 of the terminal 40 is larger than that of the pillar electrode 31 of the terminal 30. As illustrated in FIG. 3A, for example, the pillar electrode 41 is formed over a region 22 of the opening portion 22a of the insulating film 20. In the example of FIG. 3A, the pillar electrode 41 is formed in this way over the region 22 of the opening portion 22a. Unlike the pillar electrode 31, the pillar electrode 41 is not formed over a peripheral portion 22b of the opening portion 22a. Accordingly, the upper surface of the pillar electrode 41 is flat or approximately flat.

The pillar electrode 31 of the terminal 30 and the pillar electrode 41 of the terminal 40 are formed by the use of various conductor materials. For example, the pillar electrode 31 and the pillar electrode 41 are formed by the use of Cu. The pillar electrode 31 and the pillar electrode 41 may be formed by the use of a conductor material, such as nickel (Ni), gold (Au), or titanium (Ti), other than Cu. Furthermore, a conductor material such as Ni, Au, or Ti, together with Cu, may be used for forming the pillar electrode 31 and the pillar electrode 41.

Various solder materials are used for forming the solder 32 over the pillar electrode 31 and forming the solder 42 over the pillar electrode 41. For example, a Sn—Ag based solder containing Sn and Ag is used for forming the solder 32 and the solder 42. Alternatively, a Sn—Ag—Cu based solder containing Sn Ag, and Cu, a Sn—Bi based solder containing Sn and bismuth (Bi), a Sn—In based solder containing Sn and indium (In), or the like may be used for forming the solder 32 and the solder 42.

The pillar electrode 31, the pillar electrode 41, and the solder 32 and the solder 42 formed over the pillar electrode 31 and the pillar electrode 41, respectively, are formed by the use of, for example, the plating method. FIG. 3A illustrates the terminal 30 having the pillar electrode 31 and the solder 32 formed by the use of the plating method and the terminal 40 having the pillar electrode 41 and the solder 42 formed by the use of the plating method. Each of lower end portions of the pillar electrode 31 and the pillar electrode 41 formed by the use of the plating method may include a seed layer (film formed by laminating, for example, Ti and Cu) (not illustrated) used for power supply at plating time.

FIG. 3B illustrates an example of the state after a wet back process by reflow of the electronic part 1 illustrated in FIG. 3A. The solder 32 of the terminal 30 and the solder 42 of the terminal 40 are melted once and then solidified, by the wet back process. Each of the solder 32 and the solder 42 has a roundish shape as a result of the action of surface tension at melting time.

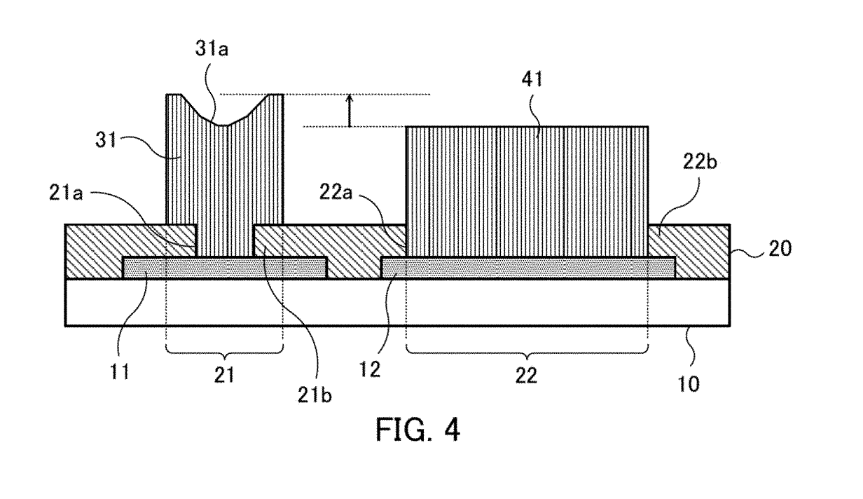

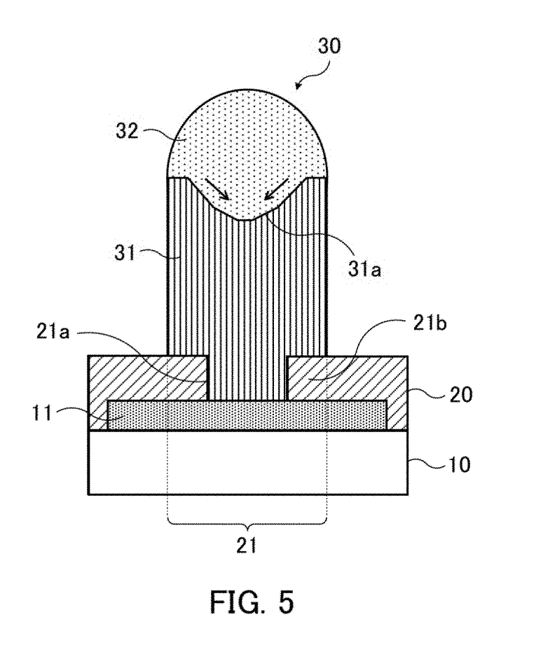

FIGS. 4 and 5 are views for describing terminals of the electronic part according to the first embodiment.

FIG. 4 illustrates the pillar electrode 31 and the pillar electrode 41 of the electronic part 1. As illustrated in FIG. 4, with the electronic part 1 the pillar electrode 31 of relatively small diameter is formed over the region 21 of the insulating film 20 including the level difference between the opening portion 21a and the peripheral portion 21b. The pillar electrode 41 of relatively large diameter is formed over the region 22 of the opening portion 22a of the insulating film 20. If the pillar electrode 31 and the pillar electrode 41 are formed over the region 21 and the region 22, respectively, of the insulating film 20 by the use of the plating method, the position of the upper end of the pillar electrode 31 of relatively small diameter formed over the region 21 including the level difference is higher than the position of the upper end of the pillar electrode 41, as illustrated in FIG. 4.

Accordingly, if the amount of the solder 32 over the pillar electrode 31 is smaller than the amount of the solder 42 over the pillar electrode 41 in the state of the electronic part 1 illustrated in FIG. 3A, the positions of the upper ends of the solder 32 and the solder 42 after the wet back process are uniformized (indicated by a chain line) as illustrated in FIG. 3B. That is to say, the height after the wet back process (height from the pad electrode 11) of the terminal 30 including the pillar electrode 31 of relatively small diameter and the solder formed thereover and the height after the wet back process (height from the pad electrode 12) of the terminal 40 including the pillar electrode 41 of relatively large diameter and the solder 42 formed thereover are uniformized. As a result, the difference in height between the terminal 30 and the terminal 40 is suppressed. Accordingly, a connection failure which occurs at the time of connecting the electronic part 1 to another electronic part is suppressed and an electronic device with high connection reliability including these electronic parts is realized.

Furthermore, the pillar electrode 31 is formed over the region 21 of the insulating film 20 including the level difference between the opening portion 21a and the peripheral portion 21b. As a result, the concavity 31a corresponding to the opening portion 21a of the insulating film 20 may be formed in the upper surface of the pillar electrode 31. If the concavity 31a is formed in the upper surface of the pillar electrode 31, force to flow to the concavity 31a of the pillar electrode 31 (indicated by an arrow) acts on the solder 32 melted at the time of the wet back process, as illustrated in FIG. 5. As a result, the solder 32 stays on the upper surface of the pillar electrode 31. This force prevents the solder 32 from flowing out from the upper surface of the pillar electrode to the outside. Accordingly, it is possible to uniformize the positions of the upper ends of the solder and the solder 42 after the wet back process and suppress the difference in height between them, while preventing the melted solder 32 from spilling onto the side of the pillar electrode 31. As a result, a connection failure which occurs at the time of connecting the electronic part 1 to another electronic part is suppressed and an electronic device with high connection reliability including these electronic parts is realized.

The height of the pillar electrode 31 of the electronic part 1, the size (volume) of the concavity 31a of the pillar electrode 31, or the height of the terminal after the wet back process including the pillar electrode 31 and the solder 32 is controlled by the thickness of the insulating film 20, the opening area of the opening portion 21a, or the like. In order to uniformize the height of the terminal 30 and the terminal after the wet back process, the thickness of the insulating film 20, the opening area of the opening portion 21a or the opening portion 22a, or the like is controlled. By doing so, the height of the pillar electrode 31 or the pillar electrode 41 or the size of the concavity 31a of the pillar electrode 31 is controlled.

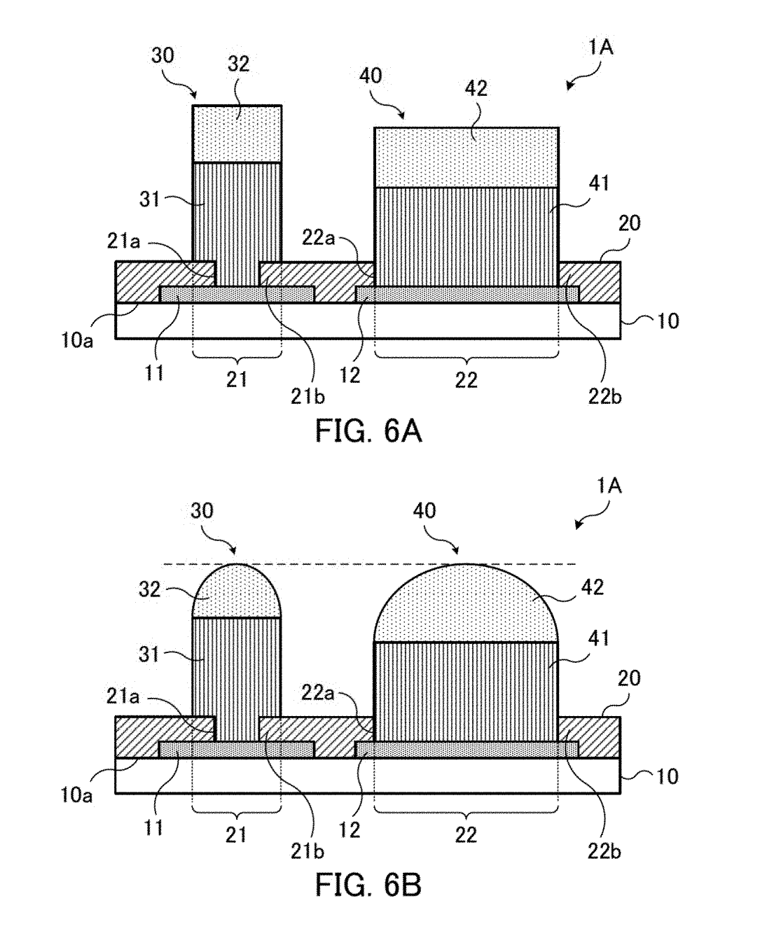

FIGS. 6A and 6B illustrate a first modification of the electronic part according to the first embodiment. FIG. 6A is a fragmentary schematic sectional view of an electronic part before a wet back process. FIG. 6B is a fragmentary schematic sectional view of the electronic part after a wet back process.

With an electronic part 1A illustrated in FIG. 6A, the upper surface of a pillar electrode 31 of relatively small diameter is flat or approximately flat. This is the same with the upper surface of a pillar electrode 41 of relatively large diameter. The electronic part 1A differs from the above electronic part 1 in this respect. There is no need to form the above concavity 31a in the upper surface of the pillar electrode 31. A concavity 31a or a clear-cut concavity 31a may be omitted from the upper surface of the pillar electrode 31 by controlling the diameter or height of the pillar electrode 31, the opening area of an opening portion 21a in an insulating film 20, conditions under which the pillar electrode 31 is plated, or the like.

With the electronic part 1A in which the upper surface of the pillar electrode 31 is flat, the pillar electrode 31 is also formed over a region 21 including a level difference between the opening portion 21a and a peripheral portion 21b thereof. As a result, the position of the upper end of the pillar electrode 31 is higher than the position of the upper end of the pillar electrode 41. At the same time that a solder 42 by whose amount a connection failure is suppressed is formed over the pillar electrode 41 at solder plating time, a solder 32 by whose amount a solder spill is suppressed at the time of a wet back process is formed over the pillar electrode 31. A proper amount of the solder 32 and a proper amount of the solder 42 are formed and the upper end of the pillar electrode 31 is set to a proper position. By doing so, a wet back process is performed. As a result, as illustrated in FIG. 6B, even if the upper surface of the pillar electrode 31 is flat, it is possible to uniformize the positions (indicated by a chain line) of the upper ends of the solder 32 and the solder 42, while suppressing a solder spill.

With the electronic part 1A the difference in height between a terminal 30 and a terminal 40 is also suppressed. Accordingly, a connection failure which is caused by the difference in height between the terminal 30 and the terminal 40 and which occurs at the time of connecting the electronic part 1A to another electronic part is suppressed and an electronic device with high connection reliability is realized.

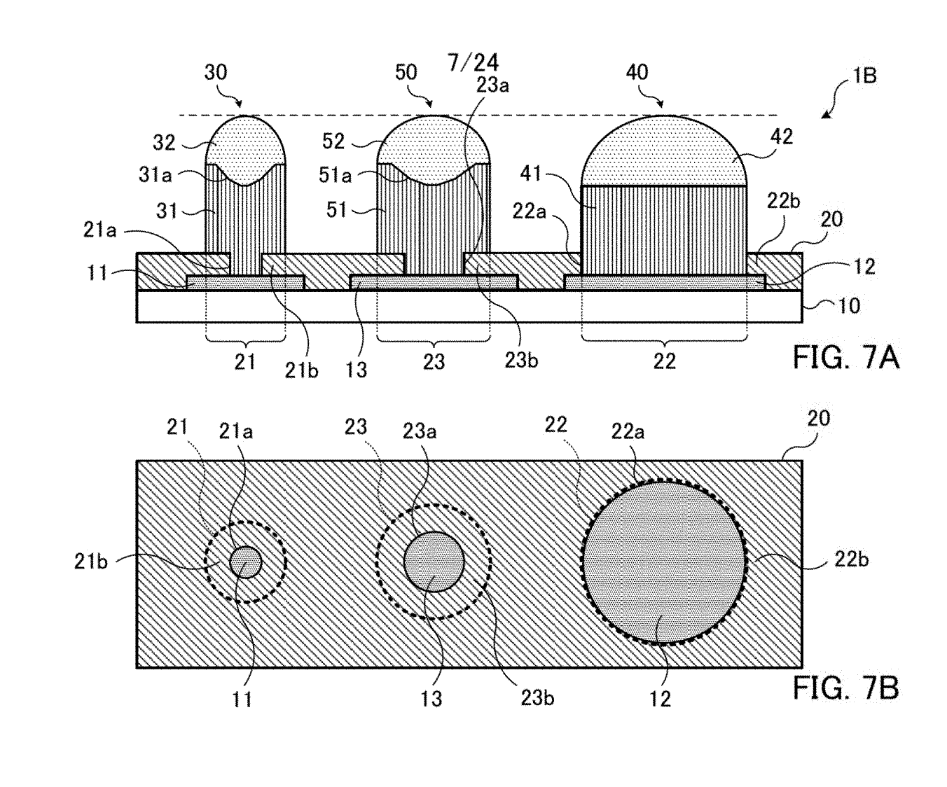

FIGS. 7A and 7B illustrate a second modification of the electronic part according to the first embodiment. FIG. 7A is a fragmentary schematic sectional view of an electronic part after a wet back process. FIG. 7B is a fragmentary schematic plan view of an insulating film before the formation of pillar electrodes.

An electronic part 1B illustrated in FIG. 7A includes a terminal 30 including a pillar electrode 31 of relatively small diameter, a terminal 40 including a pillar electrode 41 of relatively large diameter, and a terminal 50 including a pillar electrode 51 of intermediate diameter.

As illustrated in FIG. 7A, an insulating film 20 has an opening portion 23a leading to a pad electrode 13 formed over a substrate 10. The pillar electrode 51 of the terminal 50 is formed over a region 23 of the insulating film 20 including a level difference between the opening portion 23a and a peripheral portion 23b thereof. As illustrated in FIG. 7A, a portion corresponding to the opening portion 23a sinks and a concavity 51a is formed in the upper surface of the pillar electrode 51. A solder 52 is formed over the pillar electrode 51.

The pillar electrode 51 is formed by the use of various conductor materials. This is the same with the pillar electrode 31 and the pillar electrode 41. For example, the pillar electrode 51 is formed by the use of Cu. A lower end portion of the pillar electrode 51 may include a seed layer (not illustrated) used for power supply at plating time. Various solder materials are used for forming the solder 52. This is the same with a solder 32 and a solder 42. For example, a Sn—Ag based solder is used for forming the solder 52.

FIG. 7B is a schematic plan view of the insulating film 20 in which an opening portion 21a, an opening portion 22a, and the opening portion 23a are formed. FIG. 7B illustrates the positions of the pillar electrode 31, the pillar electrode 41, and the pillar electrode 51, that is to say, the outer edges of a region 21, a region 22, and the region 23 over which the pillar electrode 31, the pillar electrode 41, and the pillar electrode 51, respectively, are formed by dotted lines.

As illustrated in FIG. 7B, for example, with the electronic part 1B the opening portion 21a having a plane shape obtained by reducing the plane shape (or cross-sectional shape) of the pillar electrode 31 is formed in the region 21 of the insulating film 20 over which the pillar electrode 31 of relatively small diameter is formed. As illustrated in FIG. 7B, for example, the opening portion 22a which is equal or approximately equal in plane shape to the pillar electrode 41 is formed in the region of the insulating film 20 over which the pillar electrode 41 of relatively large diameter is formed. As illustrated in FIG. 7B, for example, the opening portion 23a having a plane shape obtained by reducing the plane shape of the pillar electrode 51 is formed in the region of the insulating film 20 over which the pillar electrode 51 of intermediate diameter is formed. The opening area of the opening portion 23a is larger than that of the opening portion 21a in which the pillar electrode 31 of relatively small diameter is formed. With the electronic part 1B the opening area of the opening portion 21a, the opening portion 22a, and the opening portion 23a formed in the insulating film 20 corresponds to the diameters of the pillar electrode 31, the pillar electrode 41, and the pillar electrode 51 respectively.

The size (volume) of a concavity 51a formed in the upper surface of the pillar electrode 51 of intermediate diameter is larger than that of a concavity 31a formed in the upper surface of the pillar electrode 31 of relatively small diameter. Therefore, even if the amount of the solder 52 formed over the pillar electrode 51 is larger than the amount of the solder 32 formed over the pillar electrode 31 of relatively small diameter, part of the thickness of the solder 52 after a wet back process is canceled out by the concavity 51a. As a result, the position of the upper end of the solder 52 is equal to the position of the upper end of the solder 32. Furthermore, even if the amount of the solder 52 formed over the pillar electrode 51 of intermediate diameter is smaller than the amount of the solder 42 formed over the pillar electrode 41 of relatively large diameter, the pillar electrode 51 is formed over the region 23 including the level difference to raise the position of the upper end of the solder 52. By doing so, the position of the upper end of the solder 52 after the wet back process is made equal to the position of the upper end of the solder 42 after the wet back process. By making the positions of the upper ends of the solder 32, the solder 42, and the solder 52 equal and uniformizing the height (indicated by a chain line) of the terminal 30, the terminal 40, and the terminal 50 including the solder 32, the solder 42, and the solder 52 respectively, a connection failure which occurs at the time of connecting the electronic part 1B to another electronic part is suppressed and an electronic device with high connection reliability is realized.

The electronic part 1B including the three pillar electrodes 31, 41, and 51 which differ in diameter is taken as an example. However, the same applies to an electronic part including a group of pillar electrodes formed of four or more kinds of pillar electrodes which differ in diameter. That is to say, an opening portion whose opening area corresponds to the diameter of each pillar electrode is formed in an insulating film (passivation film). Each pillar electrode is formed over a region of the insulating film including a level difference between an opening portion and a peripheral portion thereof or a region of an opening portion of the insulating film not including a peripheral portion thereof. By doing so, an electronic part in which the position after a wet back process of the upper end of a solder formed over each pillar electrode is uniformized is realized. Furthermore, a connection failure which occurs at the time of connecting this electronic part to another electronic part is suppressed and an electronic device with high connection reliability is realized.

In the example of FIG. 7B, the pillar electrode 31 and the pillar electrode 51 which are circular in plane shape are formed over the region 21 and the region 23 respectively. The opening portion 21a and the opening portion 23a which are circular in plane shape and whose plane shapes are obtained by reducing the plane shapes of the pillar electrode 31 and the pillar electrode 51 are formed in the region 21 and the region 23 respectively.

However, the above plane shape of the opening portion 21a in the region 21 over which the pillar electrode 31 is formed or the above plane shape of the opening portion 23a in the region 23 over which the pillar electrode 51 is formed is not limited to the plane shape illustrated in FIG. 7B.

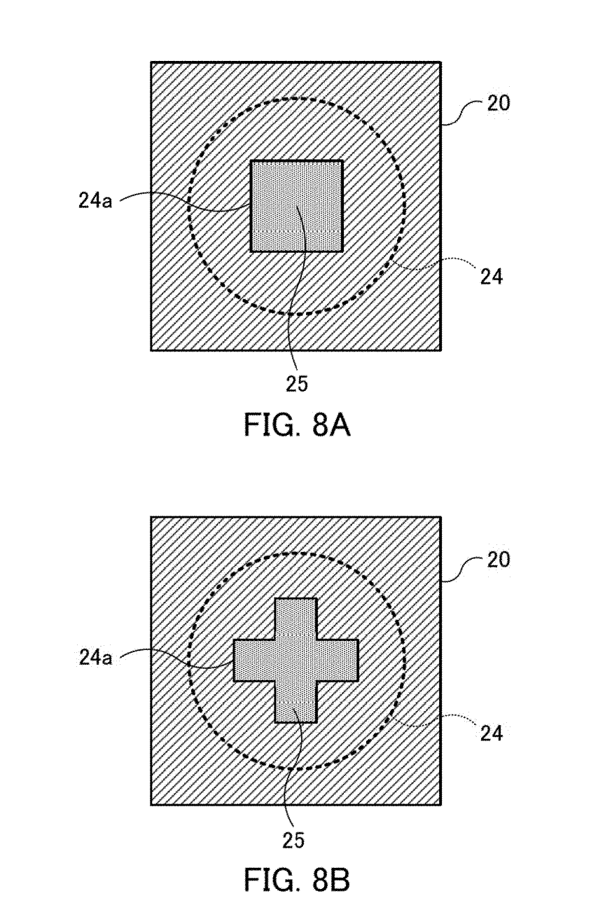

FIGS. 8A, 8B, 9A, 9B, 10A, and 10B illustrate other examples of an opening portion of the insulating film according to the first embodiment. Each of FIGS. 8A, 8B, 9A, 9B, 10A, and 10B is a fragmentary schematic plan view of an insulating film before the formation of a pillar electrode. A region over which a pillar electrode is to be formed is indicated by a dotted line.

As illustrated in FIG. 8A, an opening portion 24a in a region 24 (corresponding to the above region 21 over which the pillar electrode 31 is formed or the above region 23 over which the pillar electrode 51 is formed) of the insulating film 20 over which a pillar electrode is to be formed may be square in plane shape. As illustrated in FIG. 8B, an opening portion 24a in a region 24 over which a pillar electrode is to be formed may be crucial in plane shape. An opening portion 24a may differ from a region 24 including the opening portion 24a, that is to say, from a pillar electrode which is to be formed over the region 24 in plane shape.

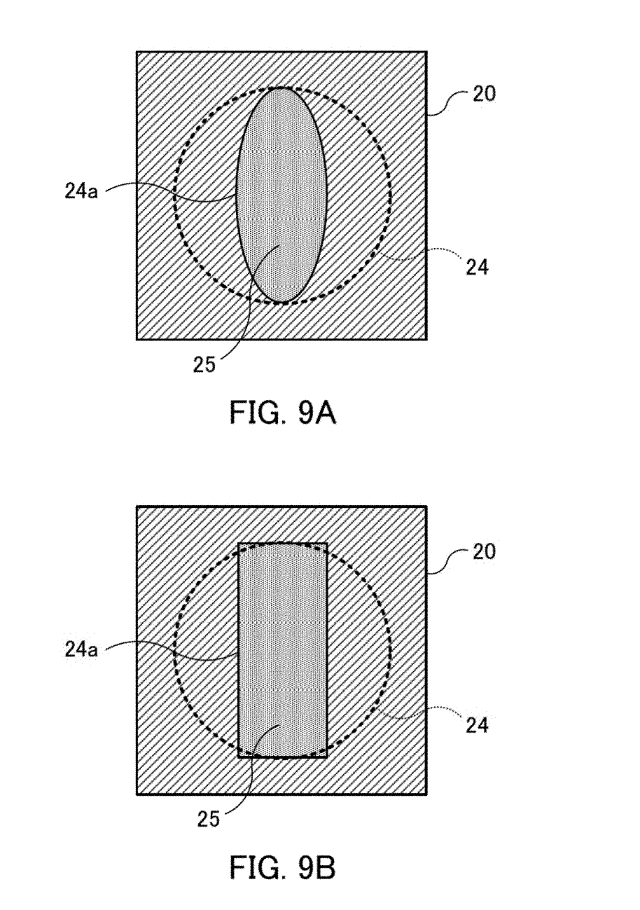

Furthermore, as illustrated in FIG. 9A, an opening portion 24a in a region 24 over which a pillar electrode is to be formed may be elliptic in plane shape. As illustrated in FIG. 9B, an opening portion 24a in a region 24 over which a pillar electrode is to be formed may be rectangular in plane shape. The length and breadth of the plane shape of an opening portion 24a may differ in this way. In the examples of FIGS. 9A and 9B, the length in the long axis direction of the opening portion 24a corresponds to the diameter of the region 24. However, an opening portion 24a which is elliptic or rectangular in plane shape and which is inside the outer edge of a region 24 in its entirety may be formed.

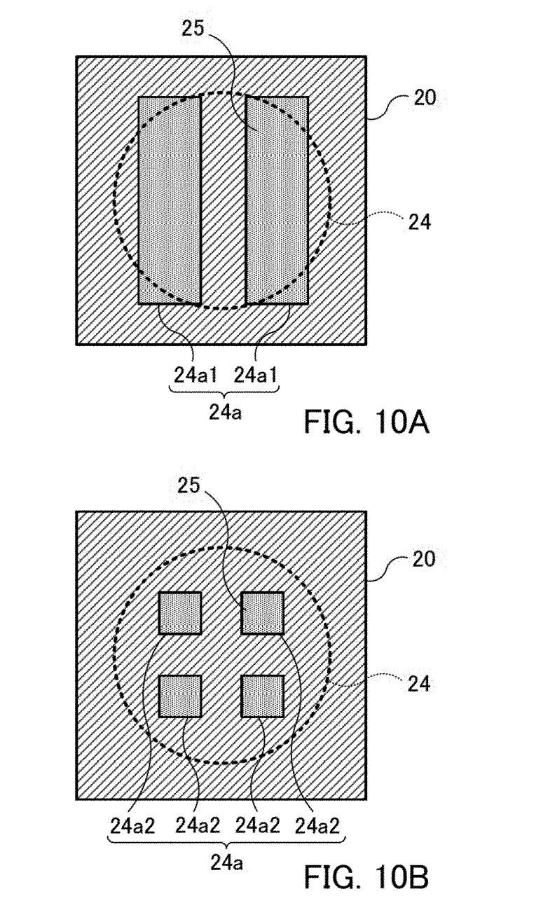

Furthermore, an opening portion 24a in a region over which a pillar electrode is to be formed may include a plurality of opening portions. As illustrated in FIG. 10A, for example, an opening portion 24a may include two opening portions 24a1 which are rectangular in plane shape. As illustrated in FIG. 10B, an opening portion 24a may include four opening portions 24a2 which are square in plane shape. An opening portion 24a formed in a region 24 over which one pillar electrode is to be formed may include the opening portions 24a1 or the opening portions 24a2 in this way. In the examples of FIGS. 10A and 10B, the group of opening portions 24a1 are rectangular in plane shape and the group of opening portions 24a2 are square in plane shape. However, a group of opening portions 24a1 and a group of opening portions 24a2 each having the plane shape of a circle, an ellipse, or a polygon other than a tetragon may be formed.

An opening portion 24a including one or more opening portions having various plane shapes may be formed in a region 24 in accordance with the examples of FIGS. 8A, 8B, 9A, 9B, 10A, and 10B. A pad electrode 25 is exposed from the opening portion 24a.

A concavity corresponding to the plane shape of the opening portion 24a is formed in the upper surface of a pillar electrode formed over the region 24. A solder is formed over the upper surface of the pillar electrode in which the concavity is formed. According to the diameter of the pillar electrode formed over the region 24 of an insulating film (passivation film), the thickness of the insulating film and the plane shape, size, and number (opening area) of the opening portion 24a in the region 24 are controlled to uniformize the positions of the upper ends of solders (height of terminals) after a wet back process.

It is desirable that the opening portion 24a whose shape and arrangement are line-symmetric with respect to a center line in planar view be formed in the region 24. By doing so, at the time of a solder formed over the upper surface of a pillar electrode being melted by a wet back process, it is possible to make the solder stay on the upper surface of the pillar electrode, while preventing the solder from gathering on one side. As a result, a solder spill is effectively suppressed.

Next, an example of an electronic part fabrication method will be described. A method for fabricating the above electronic part 1 will be taken as an example.

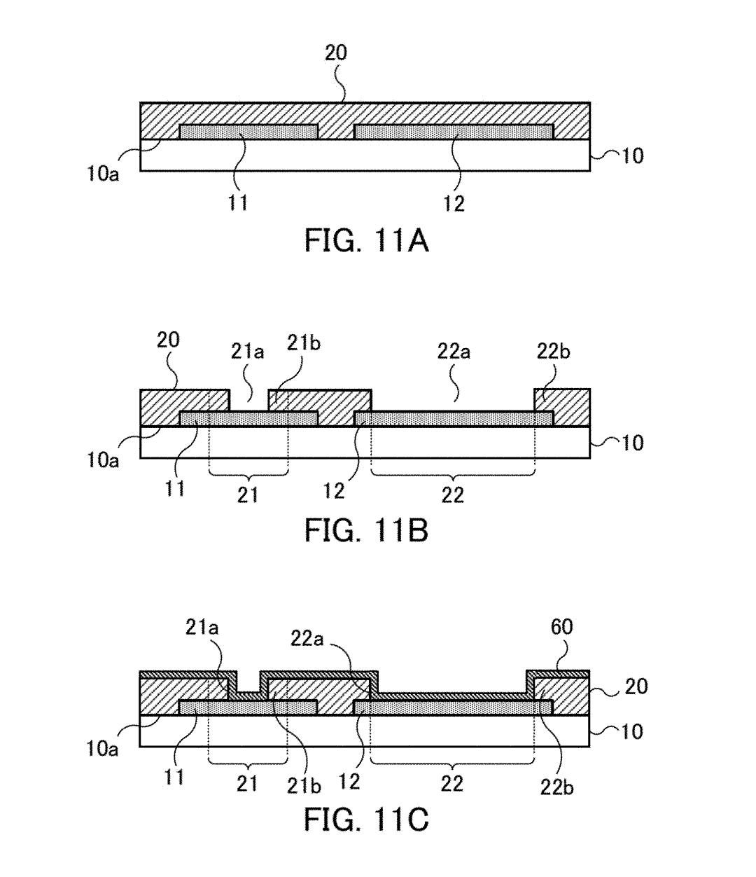

FIGS. 11A through 11C, 12A through 12C, and 13A through 13C illustrate an example of a method for fabricating the electronic part according to the first embodiment. FIGS. 11A through 11C, 12A through 12C, and 13A through 13C are fragmentary schematic sectional views of a process for fabricating the electronic part according to the first embodiment.

As illustrated in FIG. 11A, the insulating film having a determined thickness which functions as a passivation film is formed by the use of an organic insulating material or an inorganic insulating material over the substrate 10 (body of the electronic part 1) over whose surface 10a the pad electrode 11 and the pad electrode 12 are formed.

As illustrated in FIG. 11B, the opening portion 21a and the opening portion 22a leading to the pad electrode 11 and the pad electrode 12, respectively, are then formed. If the insulating film 20 is formed by the use of a photosensitive organic insulating material, then a photolithography technique is used. Exposure and development are performed on the insulating film 20. If the insulating film 20 is formed by the use of a non-photosensitive organic insulating material or an inorganic insulating material, then the photolithography technique and an etching technique are used. A resist pattern is formed and the insulating film 20 is etched with the resist pattern as a mask. For example, these techniques are used for forming in the insulating film 20 the opening portion 21a leading to the pad electrode 11 and the opening portion 22a leading to the pad electrode 12. At this time the plane shape, size, and number of each of the opening portion 21a and the opening portion 22a are prescribed. In this example, the opening area of the opening portion 22a is larger than that of the opening portion 21a.

As illustrated in FIG. 11C, a seed layer 60 is then formed. For example, a Ti film and a Cu film each having a determined thickness are formed in order as the seed layer 60.

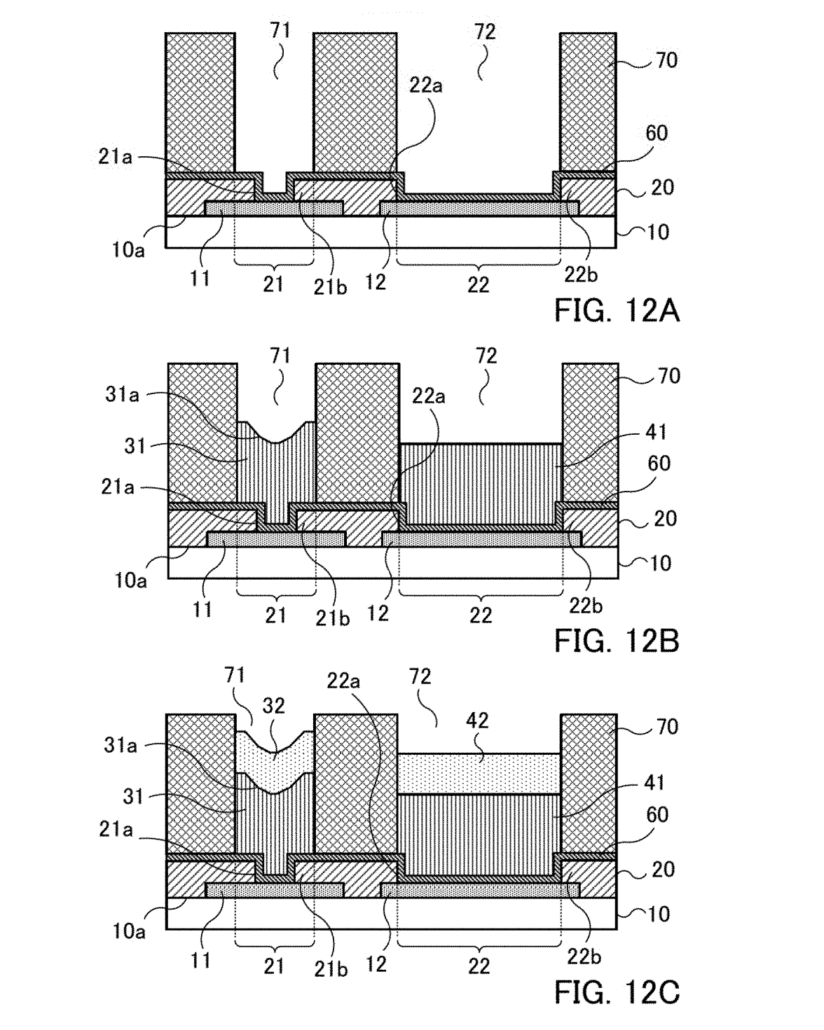

As illustrated in FIG. 12A, the photolithography technique is then used for forming a resist pattern 70 having a determined opening portion 71 and a determined opening portion 72. The opening portion 71 of the resist pattern 70 is formed in a region corresponding the region (including the opening portion 21a and the peripheral portion 21b) over which the pillar electrode 31 (terminal 30) of relatively small diameter of the electronic part 1 is formed. The diameter of the opening portion 71 corresponds to that of the pillar electrode 31. The opening portion 72 of the resist pattern 70 is formed in a region corresponding the region 22 (opening portion 22a) over which the pillar electrode 41 (terminal 40) of relatively large diameter of the electronic part 1 is formed. The diameter of the opening portion 72 corresponds to that of the pillar electrode 41.

As illustrated in FIG. 12B, copper electroplating is then performed by the use of the seed layer 60 as a power supply layer for forming the pillar electrode 31 of relatively small diameter in the opening portion 71 of the resist pattern 70 and forming the pillar electrode 41 of relatively large diameter in the opening portion 72 of the resist pattern 70. The pillar electrode 31 is formed over the region 21 of the insulating film 20 including the level difference between the opening portion 21a and the peripheral portion 21b. The pillar electrode 41 is formed over the region 22 of the opening portion 22a of the insulating film 20. The position of the upper end of the pillar electrode 31 formed over the region 21 of the insulating film 20 including the level difference is higher than the position of the upper end of the pillar electrode 41 formed over the region 22 not including such a level difference. The concavity 31a corresponding to the opening portion 21a is formed in the upper surface of the pillar electrode 31 formed over the region 21 including the level difference. The upper surface of the pillar electrode 41 formed over the region 22 not including a level difference is flat or approximately flat.

Sn—Ag based solder electroplating is then performed by the use of the seed layer 60 as a power supply layer. As a result, as illustrated in FIG. 12C, the solder 32 is formed over the pillar electrode 31 formed in the opening portion 71 of the resist pattern 70 and the solder 42 is formed over the pillar electrode 41 formed in the opening portion 72 of the resist pattern 70.

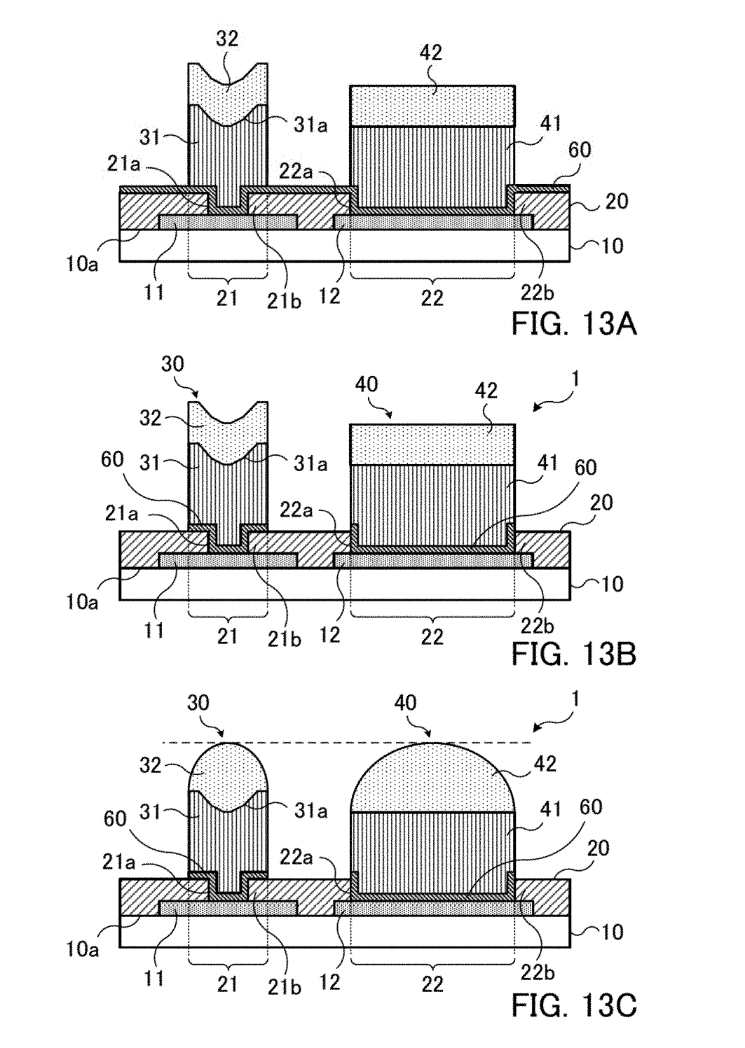

As illustrated in FIG. 13A, the resist pattern 70 is then removed. As illustrated in FIG. 13B, the seed layer 60 which is exposed after the removal of the resist pattern 70 is removed by etching. As a result, each of the pillar electrode 31 and the pillar electrode 41 formed includes the seed layer 60 in the lower end portion and the pillar electrode 31 and the pillar electrode 41 are electrically separated by the surface of the insulating film 20.

By performing the above process, the electronic part 1 before a wet back process is obtained. In this electronic part 1, the terminal 30 including the pillar electrode 31 and the solder 32 is formed over the region of the insulating film 20 including the level difference and the terminal 40 including the pillar electrode 41 and the solder 42 is formed over the region 22 not including a level difference.

When a wet back process is performed on the electronic part 1, the solder 32 and the solder 42 are heated and melted. As illustrated in FIG. 13C, the solder and the solder 42 each having a roundish shape are formed over the pillar electrode 31 and the pillar electrode 41 respectively.

The pillar electrode 31 of relatively small diameter is formed over the region 21 of the insulating film 20 including the level difference. Accordingly, the position of the upper end of the pillar electrode 31 is higher than the position of the upper end of the pillar electrode 41 of relatively large diameter formed over the region 22 not including a level difference. Furthermore, the pillar electrode 31 has the concavity 31a corresponding to the opening portion 21a in the region 21 including the level difference. As a result, after the wet back process is performed, the electronic part 1 in which the positions (indicated by a chain line) of the upper ends of the solder 32 and the solder 42 are uniformized is obtained.

When the electronic part 1 is fabricated, conditions under which the determined process is performed are controlled so as to uniformize the positions of the upper ends of the solder 32 and the solder 42 in this way after the wet back process. For example, the thickness of the insulating film 20, the plane shape, size, and number of the opening portion 21a or the opening portion 22a, the height of the pillar electrode 31 or the pillar electrode 41, the size of the concavity 31a of the pillar electrode 31, or the amount of the solder 32 or the solder 42 is controlled.

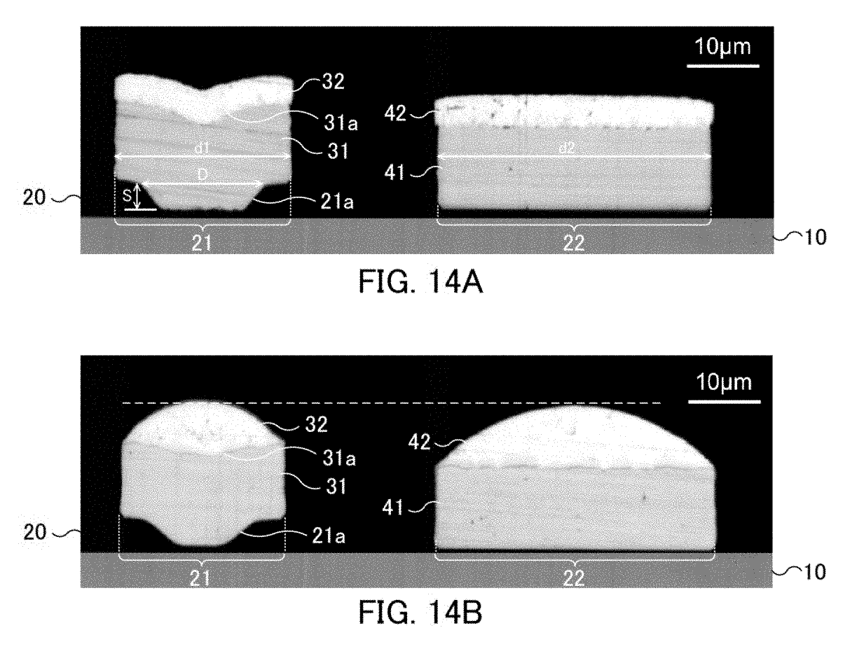

FIGS. 14A and 14B are examples of an image of a section of an electronic part.

FIGS. 14A and 14B are examples of an image of a section of an electronic part in which a copper pillar electrode 31 having a diameter d1 of about 25 μm is formed over a region 21 including a level difference of an insulating film 20 formed over a substrate 10 and in which a copper pillar electrode 41 having a diameter d2 of about 40 μm is formed over a region 22 not including a level difference. FIG. 14A is an image of a section of an electronic part before a wet back process. FIG. 14B is an image of a section of an electronic part after a wet back process.

In the example of FIG. 14A, an opening portion 21a whose section has a taper shape is formed in the region 21. This opening portion 21a is obtained by controlling conditions under which steps (FIGS. 11A and 11B) to form the opening portion 21a is performed. The diameter D of the opening portion 21a of the insulating film 20 is about 15 μm. A level difference S in the region 21 of the insulating film 20 is about 4 μm. A solder 32 is formed over the pillar electrode 31 over the region 21. A solder 42 is formed over the pillar electrode 41 over the region 22.

As indicated in FIG. 14A, the position of the upper end of the pillar electrode 31 formed over the region 21 including the level difference S is higher than the position of the upper end of the pillar electrode 41 formed over the region 22 not including a level difference. A concavity 31a is formed in the upper surface of the pillar electrode 31. The upper surface of the pillar electrode 41 is flat or approximately flat.

When the wet back process is performed, the solder 32 and the solder 42 are melted. As a result, as indicated in FIG. 14B, each of the solder 32 and the solder 42 has a roundish shape. As can be seen from FIG. 14B, the solder 32 stays on the upper surface of the pillar electrode 31 in which the concavity 31a is formed. An outflow of the solder 32 to the side of the pillar electrode 31 is not observed and the avoidance of a solder spill is ascertained. In addition, it is ascertained from FIG. 14B that the position of the upper end of the solder 32 over the pillar electrode 31 and the position of the upper end of the solder 42 over the pillar electrode 41 are uniformized (indicated by a chain line).

If, as in the examples of FIGS. 14A and 14B, the opening portion 21a whose section has a taper shape is formed in the region 21 of the insulating film 20 over which the pillar electrode 31 is formed, the generation of a void is effectively suppressed in the corners of the opening portion 21a at the time of depositing a conductor material for forming the pillar electrode 31.

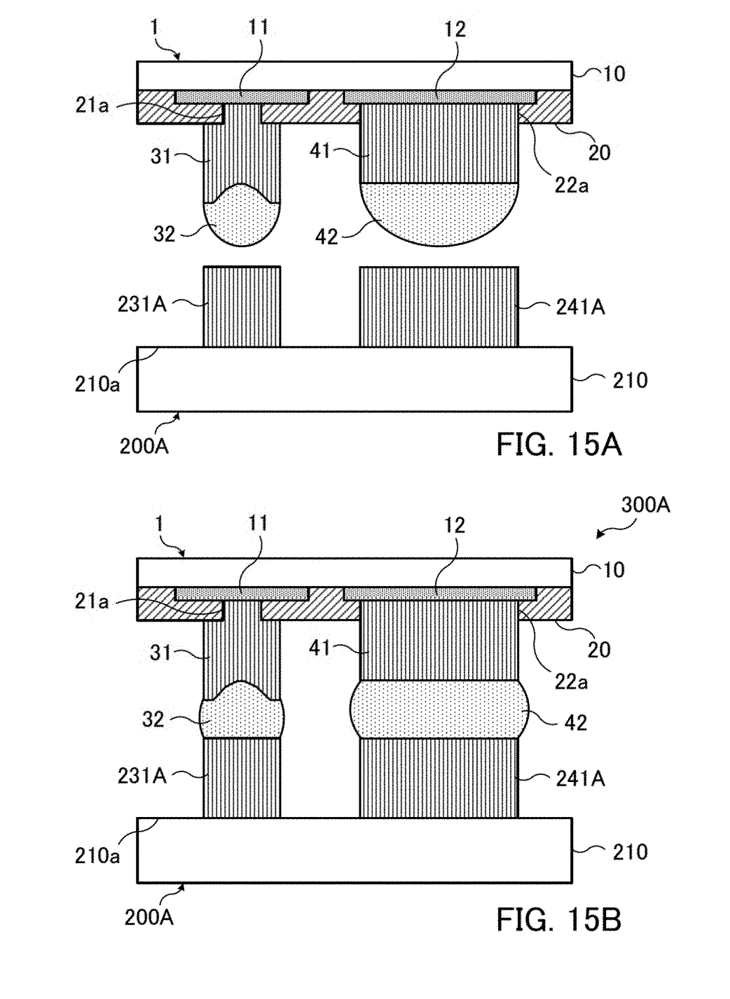

FIGS. 15A and 15B illustrate a first example of connection between the electronic part according to the first embodiment and another electronic part. FIG. 15A is a fragmentary schematic sectional view of a state before connection. FIG. 15B is a fragmentary schematic sectional view of a state after connection.

As illustrated in FIGS. 15A and 15B, for example, the above electronic part 1 is connected electrically and mechanically to another electronic part 200A.

For example, the electronic part 200A includes a semiconductor device, a circuit board, a group of semiconductor devices, a group of circuit boards, or the like. A pillar electrode 231A and a pillar electrode 241A electrically connected to internal circuit elements are formed as external connection terminals over a surface 210a of a substrate 210 which is a body of the electronic part 200A. The positions and diameters of the pillar electrode 231A and the pillar electrode 241A of the electronic part 200A correspond to the positions and diameters of the pillar electrode 31 and the pillar electrode 41, respectively, of the electronic part 1.

As illustrated in FIG. 15A, when the electronic part 200A and the electronic part 1 after a wet back process are connected, alignment between the pillar electrode 31 of the electronic part 1 and the pillar electrode 231A of the electronic part 200A and alignment between the pillar electrode 41 of the electronic part 1 and the pillar electrode 241A of the electronic part 200A are performed. As a result, the pillar electrode 31 and the pillar electrode 231A are disposed opposite each other and the pillar electrode 41 and the pillar electrode 241A are disposed opposite each other. The solder 32 over the pillar electrode 31 and the solder 42 over the pillar electrode 41 are then heated and melted by reflow and are bonded to the pillar electrode 231A and the pillar electrode 241A respectively. By doing so, an electronic device 300A illustrated in FIG. 15B is obtained. In the electronic device 300A, the pillar electrode 31 of the electronic part 1 and the pillar electrode 231A of the electronic part 200A are connected electrically and mechanically via the solder 32 and the pillar electrode 41 of the electronic part 1 and the pillar electrode 241A of the electronic part 200A are connected electrically and mechanically via the solder 42.

As stated above, with the electronic part 1 the positions of the upper ends of the solder 32 and the solder 42 after the wet back process are uniformized. Accordingly, at the time of the connection between the electronic part 1 and the electronic part 200A illustrated in FIGS. 15A and 15B, the solder 32 and the solder 42 are connected to the pillar electrode 231A and the pillar electrode 241A respectively. At this time nonconnection or a connection failure, such as a deficiency of connection strength, is suppressed. As a result, the electronic device 300A with high connection reliability is realized.

If a solder is formed over each of the pillar electrode 231A and the pillar electrode 241A of the electronic part 200A and a wet back process is performed before the connection between the electronic part 1 and the electronic part 200A, the positions of the upper ends of the solder over the pillar electrode 231A and the solder over the pillar electrode 241A are uniformized in advance in accordance with the example of the electronic part 1.

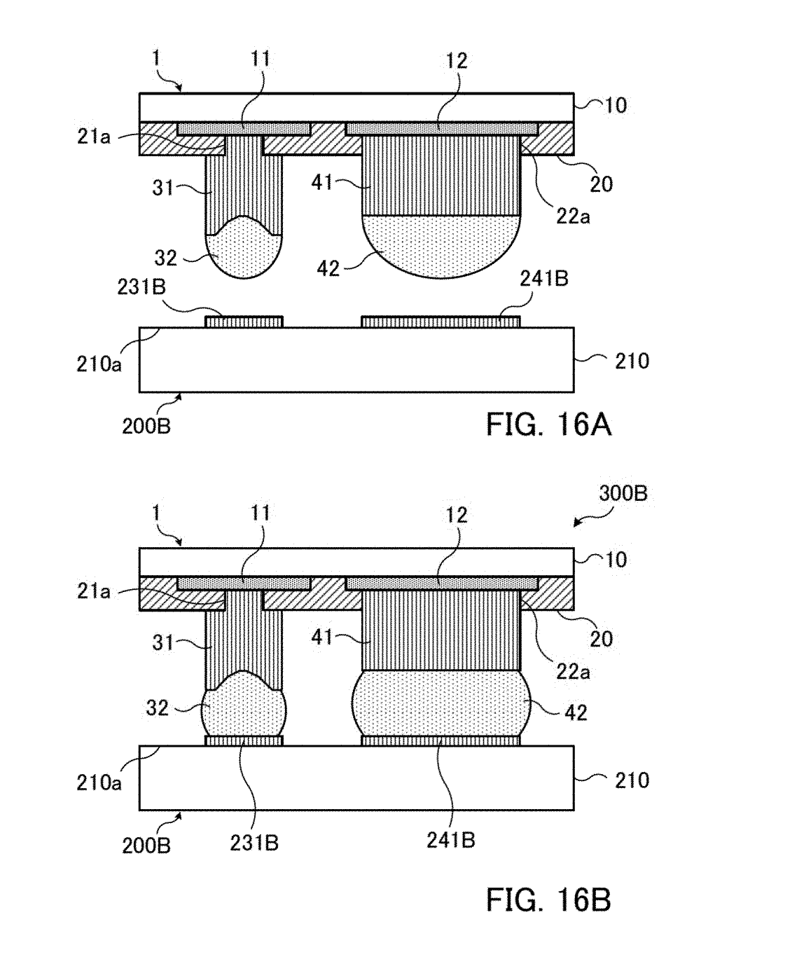

FIGS. 16A and 16B illustrate a second example of connection between the electronic part according to the first embodiment and another electronic part. FIG. 16A is a fragmentary schematic sectional view of a state before connection. FIG. 16B is a fragmentary schematic sectional view of a state after connection.

In this example, the electronic part 1 after a wet back process is connected to an electronic part 200B. The electronic part 200B includes a pad electrode 231B and a pad electrode 241B as external connection terminals over a surface 210a of a substrate 210 which is a body of the electronic part 200B. For example, the electronic part 200B includes a semiconductor device, a circuit board, a group of semiconductor devices, a group of circuit boards, or the like. The pad electrode 231B and the pad electrode 241B are electrically connected to circuit elements inside the substrate 210 and are formed in positions corresponding to the pillar electrode 31 and the pillar electrode 41, respectively, of the electronic part 1.

As illustrated in FIG. 16A, when the electronic part 200B and the electronic part 1 after the wet back process are connected, alignment between the pillar electrode 31 of the electronic part 1 and the pad electrode 231B of the electronic part 200B and alignment between the pillar electrode 41 of the electronic part 1 and the pad electrode 241B of the electronic part 200B are performed. As a result, the pillar electrode 31 and the pad electrode 231B are disposed opposite each other and the pillar electrode 41 and the pad electrode 241B are disposed opposite each other. The solder 32 over the pillar electrode 31 and the solder 42 over the pillar electrode 41 are then heated and melted by reflow and are bonded to the pad electrode 231B and the pad electrode 241B respectively. By doing so, an electronic device 300B illustrated in FIG. 16B is obtained. In the electronic device 300B, the pillar electrode 31 of the electronic part 1 and the pad electrode 231B of the electronic part 200B are connected electrically and mechanically via the solder 32 and the pillar electrode 41 of the electronic part 1 and the pad electrode 241B of the electronic part 200B are connected electrically and mechanically via the solder 42.

With the electronic part 1 the positions of the upper ends of the solder 32 and the solder 42 after the wet back process are uniformized. Accordingly, at the time of connection between the solder 32 and the pad electrode 231B and connection between the solder 42 and the pad electrode 241B illustrated in FIGS. 16A and 16B, nonconnection or a connection failure, such as a deficiency of connection strength, is suppressed. As a result, the electronic device 300B with high connection reliability is realized.

FIGS. 15A and 15B illustrate the connection between the electronic part 1 and the electronic part 200A. FIGS. 16A and 16B illustrate the connection between the electronic part 1 and the electronic part 200B. In accordance with the example of FIGS. 15A and 15B or FIGS. 16A and 16B, an electronic device with high connection reliability is obtained by connecting the above electronic part 1A or 1B to another electronic part including a corresponding group of pillar electrodes or pad electrodes.

A combination of electronic parts to be connected is a combination of a semiconductor chip and a circuit board, a combination of a semiconductor package and a circuit board, a combination of a semiconductor chip and a semiconductor package, a combination of semiconductor chips, a combination of semiconductor packages, a combination of circuit boards, or the like. Furthermore, a combination of electronic parts to be connected may be a combination of an electronic part after dicing and an electronic part after dicing, a combination of electronic parts before dicing and electronic parts after dicing, or a combination of electronic parts before dicing and electronic parts before dicing. If electronic parts before dicing and electronic parts after dicing are connected or electronic parts before dicing and electronic parts before dicing are connected, individual electronic devices are obtained by dicing after connection.

The first embodiment has been described. In the first embodiment, an electronic part includes a group of pillar electrodes which differ in diameter. A pillar electrode of relatively small diameter is formed over a region of an insulating film (passivation film) including a level difference between an opening portion and a peripheral portion thereof. A pillar electrode of relatively large diameter is formed over a region of the insulating film including a level difference between an opening portion having a relatively large opening area and a peripheral portion thereof or is formed over a region of an opening portion of the insulating film not including such a level difference. By adopting this structure, the positions of the upper ends of solders formed over the pillar electrodes which differ in diameter are uniformized. As a result, nonconnection or a connection failure, such as a deficiency of connection strength, which occurs at the time of connecting this electronic part to another electronic part is suppressed and an electronic device including a group of electronic parts with high connection reliability is realized.

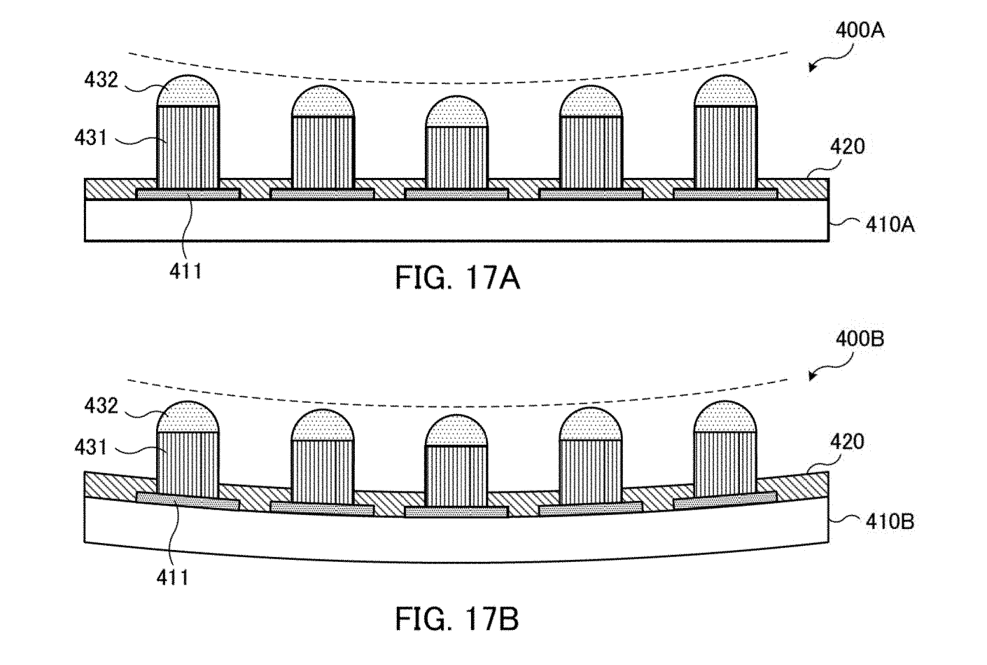

By the way, there may be variation in the height of a group of pillar electrodes in an electronic part caused by the arrangement of the group of pillar electrodes in the electronic part. This problem will be described by reference to FIGS. 17A and 17B.

FIGS. 17A and 17B are views for describing variation in the height of a group of pillar electrodes.

FIG. 17A illustrates an electronic part 400A. In the electronic part 400A, pad electrodes 411 over a substrate 410A, which is a body of the electronic part 400A, are exposed from an insulating film (passivation film) 420. A group of pillar electrodes 431 are formed by electroplating over the pad electrodes 411. Furthermore, a group of solders 432 are formed over the group of pillar electrodes 431. For example, the electronic part 400A includes a semiconductor device, a circuit board, a group of semiconductor devices, a group of circuit boards, or the like.

As illustrated in FIG. 17A, if the group of pillar electrodes 431 and the group of solders 432 are formed by electroplating over the substrate 410A, there may be variation in the positions of the upper ends (height from the pad electrodes 411) of the group of pillar electrodes 431 and the group of solders 432 from the nature of the electroplating. To be concrete, the positions of the upper ends of the group of pillar electrodes 431 and the group of solders 432 may be low in a central portion of the substrate 410A and be high in an outer peripheral portion of the substrate 410A.

Furthermore, FIG. 17B illustrates an electronic part 400B. A substrate 410B, which is a body of the electronic part 400B, is warped. For example, the electronic part 400B includes a semiconductor device, a circuit board, a group of semiconductor devices, a group of circuit boards, or the like.

The substrate 410B may be warped because of the difference in thermal expansion coefficient between materials or its thinness. It is assumed that a group of pillar electrodes 431 and a group of solders 432 whose upper ends are at uniform positions are formed over pad electrodes 411 over the substrate 410B which are exposed from an insulating film 420. As illustrated in FIG. 17B, a warp of the substrate 410B causes variation in the positions of the upper ends of the group of pillar electrodes 431 and the group of solders 432.

The variation in the positions of the upper ends of the group of pillar electrodes 431 and the group of solders 432 illustrated in FIG. 17A or 17B may cause a connection failure at the time of connecting the electronic part 400A or the electronic part 400B to another electronic part.

Accordingly, a technique indicated in a second embodiment described below will be adopted. By doing so, an electronic part connected to another electronic part with high reliability and an electronic device including a group of electronic parts connected with high reliability are realized.

A second embodiment will now be described.

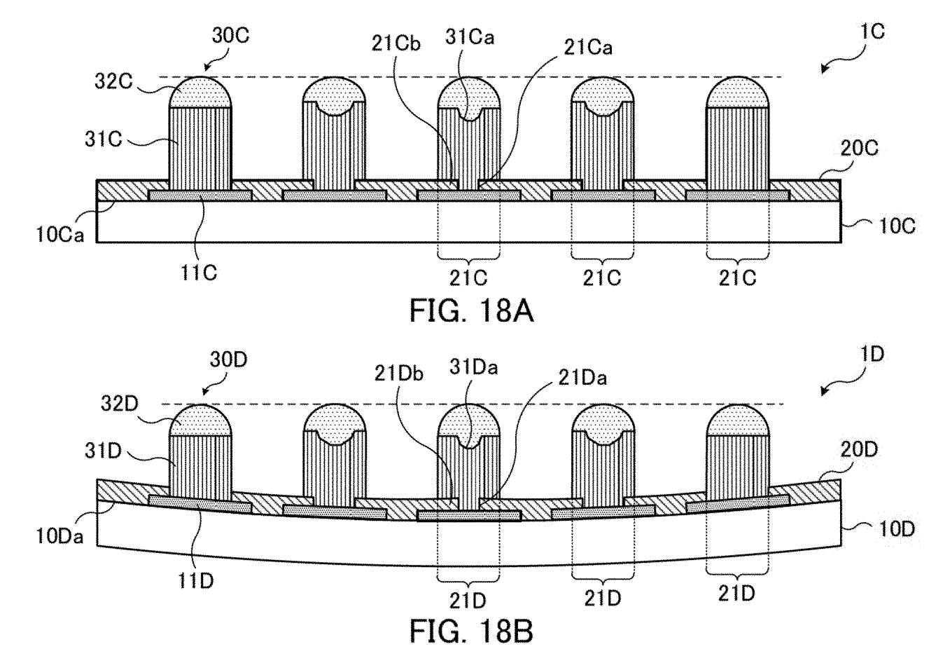

FIGS. 18A and 18B illustrate examples of an electronic part according to a second embodiment. Each of FIGS. 18A and 18B is a fragmentary schematic sectional view of an electronic part after a wet back process.

An electronic part 1C illustrated in FIG. 18A includes a substrate 10C over whose surface 10Ca a group of pad electrodes 11C are formed, an insulating film 20C having a group of opening portions 21Ca leading to the group of pad electrodes 11C, respectively, formed over the substrate 10C, and a group of terminals 30C protruding above the insulating film 20C.

For example, the electronic part 1C includes a semiconductor device, a circuit board, a group of semiconductor devices, a group of circuit boards, or the like. The substrate 10C is a body of the electronic part 1C. The pad electrodes 11C are electrically connected to circuit elements inside the substrate 10C. The pad electrodes 11C are formed by the use of a conductor material such as Al or Cu.

The insulating film 20C functions as a passivation film. The insulating film 20C is formed by the use of an organic insulating material or an inorganic insulating material. Of the group of opening portions 21Ca formed in the insulating film 20C, for example, the opening area of an opening portion 21Ca over a central portion of the substrate 10C is small and the opening area of an opening portion 21Ca becomes larger toward an outer peripheral portion of the substrate 10C.

Each of the group of terminals 30C has a pillar electrode 31C and a solder 32C formed thereover. The group of pillar electrodes 31C are formed by the use of a conductor material such as Cu. Th group of solders 32C are formed by the use of a solder material such as a Sn—Ag based solder. The group of pillar electrodes 31C are equal or approximately equal in diameter. The group of pillar electrodes 31C are formed by electroplating.

A pillar electrode 31C over the central portion of the substrate 10C is formed over a region 21C including a level difference between the opening portion 21Ca and a peripheral portion 21Cb thereof. A concavity 31Ca is formed in the upper surface of this pillar electrode 31C. A pillar electrode 31C over the outer peripheral portion of the substrate 10C is formed over a region 21C of an opening portion 21Ca. The upper surface of this pillar electrode 31C is flat or approximately flat. A pillar electrode 31C over an intermediate portion of the substrate 10C is formed over a region 21C including a level difference between an opening portion 21Ca having an intermediate opening area and a peripheral portion 21Cb thereof. The size of a concavity 31Ca formed in the upper surface of this pillar electrode 31C is larger than that of the concavity 31Ca formed in the upper surface of the pillar electrode 31C over the central portion of the substrate 10C.

As has been described, with the electronic part 1C of FIG. 18A in which the group of pillar electrodes 31C are formed by electroplating, the opening area of each opening portion 21Ca and the size of each concavity 31Ca are controlled from the central portion toward the outer peripheral portion of the substrate 10C. By doing so, the positions of the upper ends of the group of solders 32C are uniformized (indicated by a chain line). As illustrated in FIG. 17A, the group of pillar electrodes 431 become higher from the central portion toward the outer peripheral portion of the substrate 410A by electroplating. As illustrated in FIG. 18A, however, by controlling the opening area of each opening portion 21Ca and the size of each concavity 31Ca, the positions of the upper ends of the group of solders 32C are uniformized.

Furthermore, an electronic part 1D illustrated in FIG. 18B includes a substrate 10D over whose surface 10Da a group of pad electrodes 11D are formed, an insulating film 20D having a group of opening portions 21Da leading to the group of pad electrodes 11D, respectively, formed over the substrate 10D, and a group of terminals 30D protruding above the insulating film 20D.

For example, the electronic part 1D includes a semiconductor device, a circuit board, a group of semiconductor devices, a group of circuit boards, or the like. The substrate 10D is a body of the electronic part 1D. The pad electrodes 11D are electrically connected to circuit elements inside the substrate 10D. The pad electrodes 11D are formed by the use of a conductor material such as Al or Cu. In this example, the substrate 10D is warped and is concave on the surface 10Da side (convex on a side opposite the surface 10Da side). This is the same with FIG. 17B.

The insulating film 20D functions as a passivation film. The insulating film 20D is formed by the use of an organic insulating material or an inorganic insulating material. Of the group of opening portions 21Da formed in the insulating film 20D, for example, the opening area of an opening portion 21Da over a central portion of the substrate 10D is small and the opening area of an opening portion 21Da becomes larger toward an outer peripheral portion of the substrate 10D.

Each of the group of terminals 30D has a pillar electrode 31D and a solder 32D formed thereover. The group of pillar electrodes 31D are formed by the use of a conductor material such as Cu. Th group of solders 32D are formed by the use of a solder material such as a Sn—Ag based solder. The group of pillar electrodes 31D are equal or approximately equal in diameter and height from the pad electrodes 11D.

For example, a pillar electrode 31D over the central portion of the substrate 10D is formed over a region 21D including a level difference between the opening portion 21Da and a peripheral portion 21Db thereof. A concavity 31Da is formed in the upper surface of this pillar electrode 31D. Furthermore, a pillar electrode 31D over the outer peripheral portion of the substrate 10D is formed over a region 21D of an opening portion 21Da. The upper surface of this pillar electrode 31D is flat or approximately flat. A pillar electrode 31D over an intermediate portion of the substrate 10D is formed over a region 21D including a level difference between an opening portion 21Da having an intermediate opening area and a peripheral portion 21Db thereof. The size of a concavity 31Da formed in the upper surface of this pillar electrode 31D is larger than that of the concavity 31Da formed in the upper surface of the pillar electrode 31D over the central portion of the substrate 10D.

As has been described, with the electronic part 1D of FIG. 18B in which the group of pillar electrodes 31D are formed over the substrate 10D that is concavely warped, the opening area of each opening portion 21Da and the size of each concavity 31Da are controlled from the central portion toward the outer peripheral portion of the substrate 10D. By doing so, the positions of the upper ends of the group of solders 32D are uniformized (indicated by a chain line).

In FIG. 18A or 18B, the pillar electrode 31C or 31D over the outer peripheral portion of the substrate 10C or 10D is formed over the region (opening portion 21Ca or 21Da) of the insulating film 20C or 20D not including a level difference. As with the other pillar electrodes 31C or 31D, however, the pillar electrode 31C or 31D over the outer peripheral portion of the substrate 10C or 10D may be formed over a region of the insulating film 20C or 20D including a level difference between an opening portion 21Ca or 21Da having a determined opening area and a peripheral portion 21Cb or 21Db thereof. By doing so, the positions of the upper ends of the group of solders 32C or 32D are also uniformized.

The above technique is applicable not only to the electronic parts 1C and 1D illustrated in FIGS. 18A and 18B, respectively, but also to various electronic parts in which there is variation in the positions of the upper ends of a group of solders formed over a group of pillar electrodes respectively. That is to say, if the position of the upper end of a solder formed over a pillar electrode is low, a relatively small opening portion is formed in an insulating film (passivation film) in a region over which the pillar electrode is formed. The pillar electrode is formed over a region including a level difference between the opening portion and a peripheral portion thereof. If the position of the upper end of a solder formed over a pillar electrode is high, a relatively large opening portion is formed in the insulating film (passivation film) in a region over which the pillar electrode is formed. The pillar electrode is formed over a region including a level difference between the opening portion and a peripheral portion thereof. Alternatively, if the position of the upper end of a solder formed over a pillar electrode is high, an opening portion is formed in the insulating film (passivation film) in a region over which the pillar electrode is formed. The pillar electrode is formed over the region not including a level difference. By doing so, the positions of the upper ends of a group of solders formed over a group of pillar electrodes, respectively, are uniformized in various electronic parts.

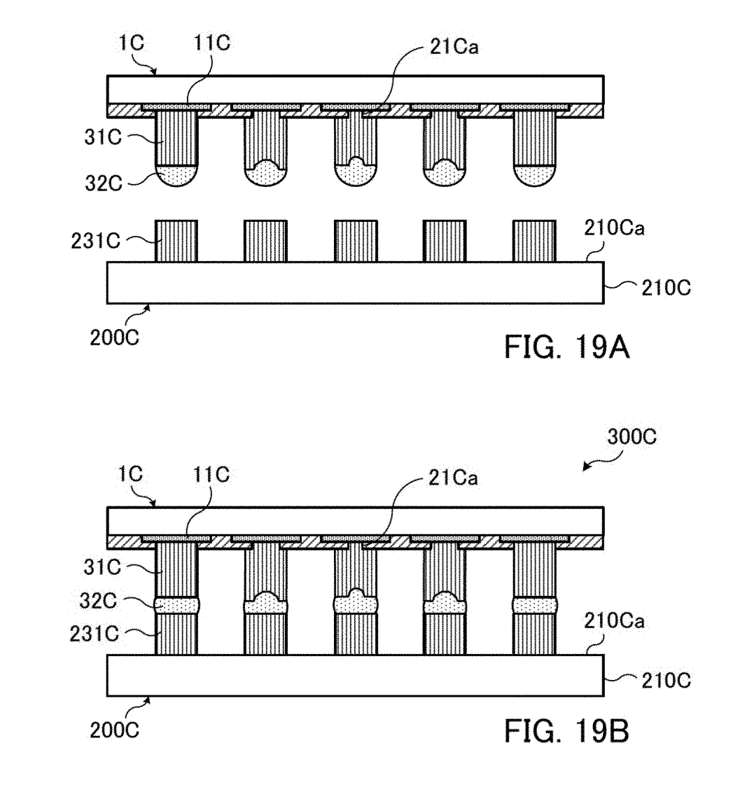

FIGS. 19A and 19B illustrate an example of connection between the electronic part according to the second embodiment and another electronic part. FIG. 19A is a fragmentary schematic sectional view of a state before connection. FIG. 19B is a fragmentary schematic sectional view of a state after connection.

Description will be given with connection between the electronic part 1C illustrated in FIG. 18A and another electronic part 200C as an example. For example, the electronic part 200C includes a semiconductor device, a circuit board, a group of semiconductor devices, a group of circuit boards, or the like. A group of pillar electrodes 231C electrically connected to internal circuit elements are formed over a surface 210Ca of a substrate 210C which is a body of the electronic part 200C. The positions and diameters of the group of pillar electrodes 231C of the electronic part 200C correspond to the positions and diameters of the group of pillar electrodes 31C, respectively, of the electronic part 1C.

As illustrated in FIG. 19A, when the electronic part 200C and the electronic part 1C after a wet back process are connected, alignment between the group of pillar electrodes 31C of the electronic part 1C and the group of pillar electrodes 231C of the electronic part 200C is performed. As a result, the group of pillar electrodes 31C and the group of pillar electrodes 231C are disposed opposite each other. The group of solders 32C over the group of pillar electrodes 31c are then heated and melted by reflow and are bonded to the group of pillar electrodes 231C respectively. By doing so, an electronic device 300C illustrated in FIG. 19B is obtained. In the electronic device 300C, the group of pillar electrodes 31C of the electronic part 1C and the group of pillar electrodes 231C of the electronic part 200C are connected electrically and mechanically via the group of solders 32 respectively.

As stated above, with the electronic part 1C the positions of the upper ends of the group of solders 32C after the wet back process are uniformized. Accordingly, at the time of the connection between the electronic part 1C and the electronic part 200C illustrated in FIGS. 19A and 19B, the group of solders 32C are connected to the group of pillar electrodes 231C respectively. At this time nonconnection or a connection failure, such as a deficiency of connection strength, is suppressed. As a result, the electronic device 300C with high connection reliability is realized.

In the above example, the electronic part 1C is connected to the electronic part 200C including the group of pillar electrodes 231C as external connection terminals. However, the same procedure is adopted for connecting the electronic part 1C to an electronic part including not a group of pillar electrodes but a group of pad electrodes as external connection terminals.

Furthermore, the electronic part 1D illustrated in FIG. 18B is connected to another electronic part including a group of pillar electrodes or a group of pad electrodes in the same way as with the electronic part 1C.

A combination of electronic parts to be connected is a combination of a semiconductor chip and a circuit board, a combination of a semiconductor package and a circuit board, a combination of a semiconductor chip and a semiconductor package, a combination of semiconductor chips, a combination of semiconductor packages, a combination of circuit boards, or the like. Furthermore, a combination of electronic parts to be connected may be a combination of an electronic part after dicing and an electronic part after dicing, a combination of electronic parts before dicing and electronic parts after dicing, or a combination of electronic parts before dicing and electronic parts before dicing. If electronic parts before dicing and electronic parts after dicing are connected or electronic parts before dicing and electronic parts before dicing are connected, individual electronic devices are obtained by dicing after connection.

In the above description, the positions of the upper ends of a group of solders formed over a group of pillar electrodes in various electronic parts are uniformized. However, the positions of the upper ends of a group of solders may properly be controlled by the above techniques according to the height of a group of terminals included in another electronic part. For example, if there are differences in the position of an upper end among a group of terminals included in another electronic part, then control is exercised so as to raise the position(s) of the upper end(s) of one or more solders corresponding to one or more low terminals and to lower the position(s) of the upper end(s) of one or more solders corresponding to one or more high terminals. For example, a pillar electrode is formed over a region including a level difference between a relatively small opening portion formed in an insulating film (passivation film) and a peripheral portion thereof in order to raise the position(s) of the upper end(s) of one or more solders. For example, a pillar electrode is formed over a region including a level difference between a relatively large opening portion formed in the insulating film (passivation film) and a peripheral portion thereof in order to lower the position(s) of the upper end(s) of one or more solders. Alternatively, a pillar electrode is formed over an opening portion of the insulating film, that is to say, over a region not including a level difference in order to lower the position(s) of the upper end(s) of one or more solders. By using the above techniques, the height of a group of solders formed over a group of pillar electrodes is not only uniformized but also controlled at desired levels.

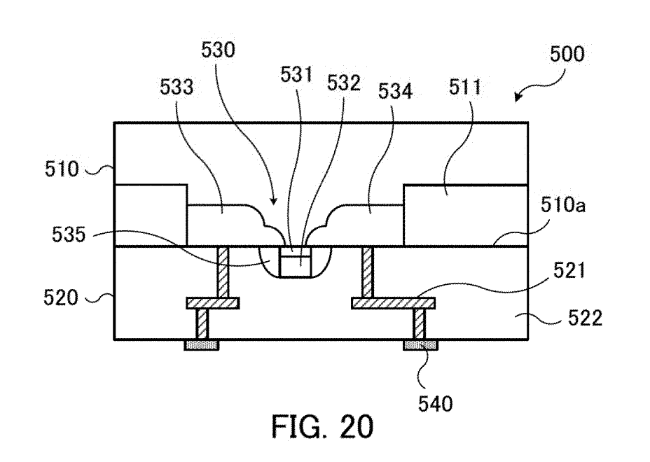

Each of FIGS. 20 through 23 illustrates an example of the basic structure of a semiconductor device (semiconductor chip or a semiconductor package) or a circuit board used as or included in each of the electronic parts 1, 1A, 1B, 1C, and 1D described in the above first and second embodiments.

FIG. 20 illustrates an example of the structure of a semiconductor chip. FIG. 20 is a fragmentary schematic sectional view of an example of a semiconductor chip.

A semiconductor chip 500 illustrated in FIG. 20 includes a semiconductor substrate 510 in which circuit elements, such as transistors, are formed and a wiring layer 520 formed over a surface 510a of the semiconductor substrate 510.

A silicon (Si) substrate, a germanium (Ge) substrate, a silicon germanium (SiGe) substrate, a gallium arsenide (GaAs) substrate, an indium phosphide (InP) substrate, or the like is used as the semiconductor substrate 510. Circuit elements, such as transistors, capacitors, and resistors, are formed in the semiconductor substrate 510. FIG. 20 illustrates a metal oxide semiconductor (MOS) transistor 530 as an example.

The MOS transistor 530 is formed in an element region demarcated by isolation regions 511 formed in the semiconductor substrate 510. The MOS transistor 530 includes a gate electrode 532 formed over the semiconductor substrate 510 with a gate insulating film 531 therebetween and a source region 533 and a drain region 534 formed in the semiconductor substrate 510 on both sides of the gate electrode 532. A spacer (sidewall) 535, which is an insulating film, is formed on a sidewall of the gate electrode 532.

The wiring layer 520 is formed over the semiconductor substrate 510 in which the MOS transistor 530 and the like are formed. The wiring layer 520 includes conductor portions 521 (wirings, vias, and the like) electrically connected to the MOS transistor 530 and the like formed in the semiconductor substrate 510 and an insulating portion 522 which covers the conductor portions 521. The conductor portions 521 are formed by the use of a conductor material such as Cu. The insulating portion 522 is formed by the use of an inorganic insulating material, such as SiO, or an organic insulating material, such as resin. A group of pad electrodes 540 electrically connected to the conductor portions 521 are formed over the wiring layer 520. The pad electrodes 540 are formed by the use of a conductor material such as Al.

The semiconductor chip 500 (body) has the above basic structure. In accordance with the example described in the above first or second embodiment, an insulating film (passivation film) and terminals each including a pillar electrode and a solder are formed over the wiring layer 520 over which the group of pad electrodes 540 are formed.

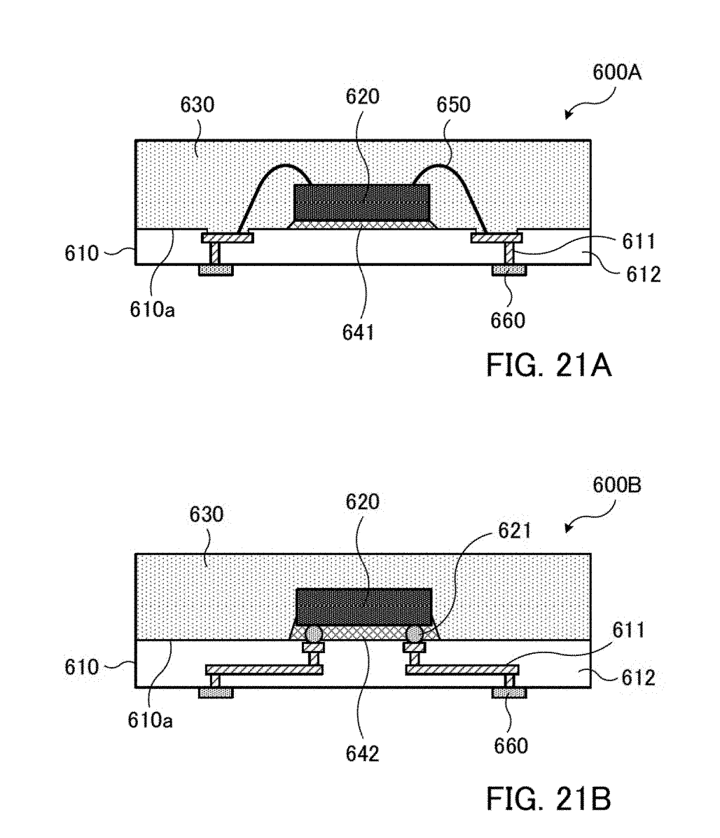

FIGS. 21A and 21B illustrate an example of the structure of a semiconductor package. Each of FIGS. 21A and 21B is a fragmentary schematic sectional view of an example of a semiconductor package.

A semiconductor package 600A illustrated in FIG. 21A or a semiconductor package 600B illustrated in FIG. 21B includes a package substrate 610, a semiconductor chip 620 mounted over the package substrate 610, and a sealing layer 630 which seals the semiconductor chip 620.

For example, a printed circuit board is used as the package substrate 610. The package substrate 610 includes conductor portions 611 (wirings, vias, and the like) and an insulating portion 612 which covers the conductor portions 611. The conductor portions 611 are formed by the use of a conductor material such as Cu. The insulating portion 612 is formed by the use of a resin material, such as phenolic resin, epoxy resin, or polyimide resin, a composite resin material obtained by impregnating glass fiber or carbon fiber with such a resin material, or the like.

With the semiconductor package 600A illustrated in FIG. 21A, the semiconductor chip 620 is attached and fixed to a surface 610a of the package substrate 610 with a die attach material 641, such as resin or a conductive paste, and is wire-bonded with a wire 650. The semiconductor chip 620 and the wire 650 are sealed with the sealing layer 630. Furthermore, with the semiconductor package 600B illustrated in FIG. 21B, the semiconductor chip 620 is flip-chip-connected to a surface 610a of the package substrate 610 with a bump 621 formed by the use of solder or the like. A space between the package substrate 610 and the semiconductor chip 620 is filled with under fill resin 642. The semiconductor chip 620 is sealed with the sealing layer 630. The sealing layer 630 is formed by the use of a resin material, such as epoxy resin, such a resin material containing an insulating filler, or the like. A group of pad electrodes 660 electrically connected to the conductor portions 611 are formed over the package substrate 610. The pad electrodes 660 are formed by the use of a conductor material such as Al.

The semiconductor package 600A (body) or the semiconductor package 600B (body) has the above basic structure. In accordance with the example described in the above first or second embodiment, an insulating film (passivation film) and terminals each including a pillar electrode and a solder are formed over the package substrate 610 over which the group of pad electrodes 660 are formed.

A plurality of semiconductor chips 620 of the same kind or different kinds may be mounted over the package substrate 610 of the semiconductor package 600A or the semiconductor package 600B. Furthermore, not only the semiconductor chip 620 but also another electronic part, such as a chip capacitor, may be mounted over the package substrate 610 of the semiconductor package 600A or the semiconductor package 600B.

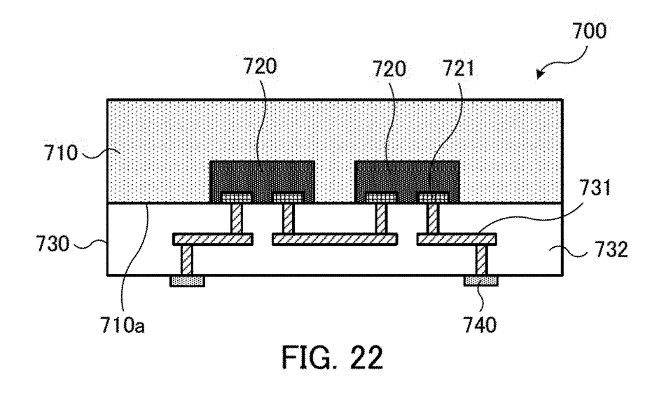

FIG. 22 illustrates another example of the structure of a semiconductor package. FIG. 22 is a fragmentary schematic sectional view of another example of a semiconductor package.

A semiconductor package 700 illustrated in FIG. 22 includes a resin layer 710, a plurality of (two, in this example) semiconductor chips 720 of the same kind or different kinds buried in the resin layer 710, and a wiring layer (rewiring layer) 730 formed over a surface 710a of the resin layer 710. The semiconductor package 700 is also called a pseudo system on a chip (SoC) or the like.

Each semiconductor chip 720 is buried in the resin layer 710 so that a surface in which a terminal 721 is arranged will be exposed. The wiring layer 730 includes conductor portions 731 (rewirings, vias, and the like) formed by the use of Cu or the like and an insulating portion 732 which covers the conductor portions 731 and which is formed by the use of a resin material or the like. A group of pad electrodes 740 electrically connected to the conductor portions 731 are formed over the wiring layer 730. The pad electrodes 740 are formed by the use of a conductor material such as Al.

The semiconductor package 700 (body) has the above basic structure. In accordance with the example described in the above first or second embodiment, an insulating film (passivation film) and terminals each including a pillar electrode and a solder are formed over the wiring layer 730 over which the group of pad electrodes 740 are formed.

One semiconductor chip 720 or three or more semiconductor chips 720 of the same kind or different kinds may be buried in the resin layer 710 of the semiconductor package 700. Furthermore, not only the semiconductor chips 720 but also another electronic part, such as a chip capacitor, may be buried in the resin layer 710 of the semiconductor package 700.

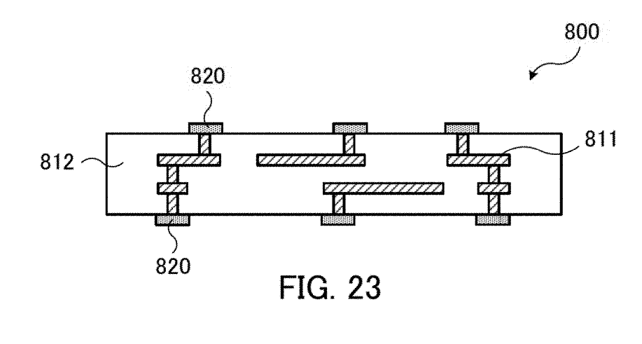

FIG. 23 illustrates an example of the structure of a circuit board. FIG. 23 is a fragmentary schematic sectional view of an example of a circuit board.

FIG. 23 illustrates a multilayer printed circuit board including a plurality of wiring layers as a circuit board 800. The circuit board 800 includes conductor portions 811 (wirings, vias, and the like) formed by the use of Cu or the like and an insulating portion 812 which covers the conductor portions 811 and which is formed by the use of a resin material or the like. A group of pad electrodes 820 electrically connected to the conductor portions 811 are formed over the insulating portion 812. The pad electrodes 820 are formed by the use of a conductor material such as Al.

The circuit board 800 (body) has the above basic structure. In accordance with the example described in the above first or second embodiment, an insulating film (passivation film) and terminals each including a pillar electrode and a solder are formed over the insulating portion 812 over which the group of pad electrodes 820 are formed.

A multilayer printed circuit board is taken as an example. However, the same applies to various circuit boards such as a buildup board formed by laminating a wiring pattern and insulating layer over front and back surfaces of a core board and an interposer in which a Si substrate, an organic substrate, or a glass substrate is used as a substrate.

In addition, an electronic device or the like obtained by connecting the electronic part 1, 1A, 1B, 1C, or 1D described in the above first or second embodiment to another electronic part is used in various electronic equipments, such as computers (personal computers, supercomputers, servers, and the like), smartphones, portable telephones, tablet terminals, sensors, cameras, audio equipments, measuring equipments, inspection equipments, and manufacturing equipments.

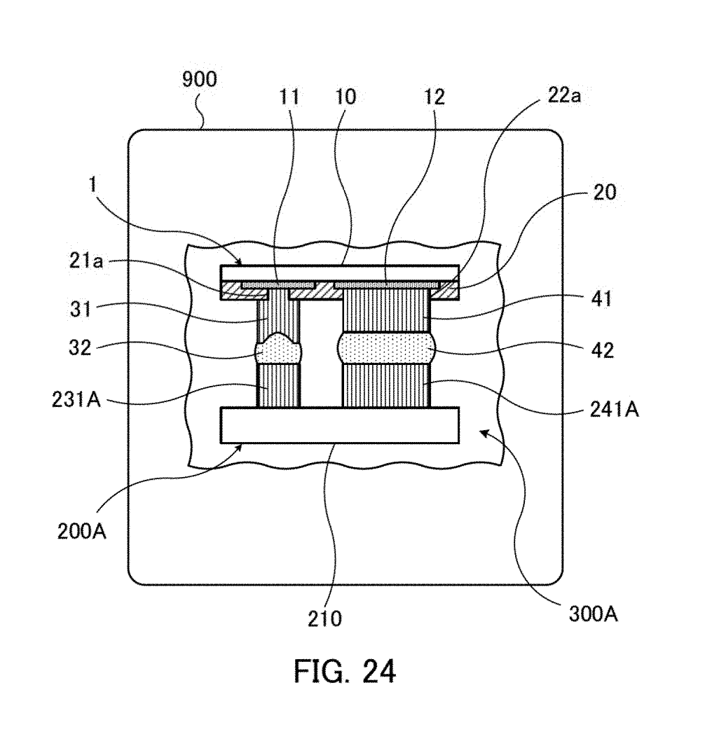

FIG. 24 illustrates an example of an electronic equipment.

FIG. 24 is a schematic view of an example of an electronic equipment. As illustrated in FIG. 24, for example, the electronic device 300A illustrated in FIG. 15B is mounted (contained) in an electronic equipment 900 taken previously as an example.

The electronic device 300A is obtained by connecting the electronic part 1 in which the positions of the upper ends of the solder 32 over the pillar electrode and the solder 42 over the pillar electrode 41 after the wet back process are uniformized to the electronic part 200A including the corresponding pillar electrode 231A and pillar electrode 241A. Because the positions of the upper ends of the solder 32 and the solder 42 after the wet back process are uniformized in the electronic part 1, a connection failure is suppressed at the time of connecting the electronic part 1 to the electronic part 200A. As a result, the electronic device 300A with high connection reliability is realized. Therefore, a high performance electronic equipment 900 with high reliability in which the electronic device 300A is mounted is realized.

The electronic device 300A is taken as an example. However, various electronic equipments in which the other electronic devices are mounted are also realized in the same way.

According to the disclosed techniques, an electronic part in which the positions of the upper ends of a group of solders over a group of pillar electrodes after a wet back process are controlled at desired levels is realized. Furthermore, an electronic device and an electronic equipment in which a group of such electronic parts are used are realized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An electronic part comprising:
a substrate;
an insulating film formed over the substrate, having a first region including a first opening portion and a first peripheral portion of the first opening portion, and having a second region including a second opening portion whose opening area is larger than an opening area of the first opening portion;
a first pillar electrode formed over the first region;
a first solder formed over the first pillar electrode;
a second pillar electrode formed over the second region; and
a second solder formed over the second pillar electrode.

2. The electronic part according to claim 1, wherein upper ends of the first solder and the second solder are at a same level from the substrate.

3. The electronic part according to claim 1, wherein the first pillar electrode has a first concavity formed as a result of sinking of a portion corresponding to the first opening portion in an upper surface over which the first solder is formed.

4. The electronic part according to claim 1, wherein the second region is the second opening portion.

5. The electronic part according to claim 1, wherein the second region includes the second opening portion and a second peripheral portion of the second opening portion.

6. The electronic part according to claim 5, wherein the second pillar electrode has a second concavity formed as a result of sinking of a portion corresponding to the second opening portion in an upper surface over which the second solder is formed.

7. The electronic part according to claim 1, wherein the first pillar electrode is smaller in diameter than the second pillar electrode.

8. The electronic part according to claim 1, wherein the first pillar electrode is equal in diameter to the second pillar electrode.

9. The electronic part according to claim 1, wherein lower ends of the first pillar electrode and the second pillar electrode are at a same level from the substrate.

10. The electronic part according to claim 1, wherein the first opening portion includes a plurality of opening portions.

11. The electronic part according to claim 1, wherein:
the first region is in a center of the substrate; and
the second region is outside the center.

12. An electronic device comprising:
a first electronic part including:
a substrate;
an insulating film formed over the substrate, having a first region including a first opening portion and a first peripheral portion of the first opening portion, and having a second region including a second opening portion whose opening area is larger than an opening area of the first opening portion;
a first pillar electrode formed over the first region; and
a second pillar electrode formed over the second region;
a second electronic part disposed opposite the first electronic part and including a first terminal formed at a position corresponding to the first pillar electrode and a second terminal formed at a position corresponding to the second pillar electrode;
a first solder formed between the first pillar electrode and the first terminal; and
a second solder formed between the second pillar electrode and the second terminal.

13. An electronic apparatus comprising an electronic device including:
a first electronic part including:
a substrate;
an insulating film formed over the substrate, having a first region including a first opening portion and a first peripheral portion of the first opening portion, and having a second region including a second opening portion whose opening area is larger than an opening area of the first opening portion;
a first pillar electrode formed over the first region; and
a second pillar electrode formed over the second region;
a second electronic part disposed opposite the first electronic part and including a first terminal formed at a position corresponding to the first pillar electrode and a second terminal formed at a position corresponding to the second pillar electrode;
a first solder formed between the first pillar electrode and the first terminal; and
a second solder formed between the second pillar electrode and the second terminal.
